(19) United States
(12) Patent Application Publication
(10) Pub. No.: US 2016/0336878 A1
(43) Pub. Date: Nov. 17, 2016

(54) Poly-actuator

(71) Applicant: Massachusetts Institute of Technology, Cambridge, MA (US)

(72) Inventors: James TORRES, Cambridge, MA (US); Haruhiko Harry ASADA, Lincoln, MA (US)

(21) Appl. No.: 15/150,724

(22) Filed: May 10, 2016

Related U.S. Application Data
(60) Provisional application No. 62/159,432, filed on May 11, 2015.

(51) Int. Cl. H02N 2/04; H01L 41/083; H01L 41/09

(52) U.S. Cl. CPC H02N 2/043; H01L 41/0986; H01L 41/083

(57) ABSTRACT

Similar to combustion engines including multiple cylinders engaged with a crankshaft, multiple piezoelectric stack actuators (PSA) engaged with a common output rod can produce smooth, long stroke motion with desired properties. In particular, when equally spaced multiple units are arranged to push sinusoidal gear teeth on the output rod, the system exhibits unique collective behaviors thanks to “harmonic” effects of the multiple units. For example, although the force-displacement characteristics of individual units are highly nonlinear, the undesirable nonlinearity, including singularity, may be eliminated. Here it presents harmonic analysis, design, and control of a class of actuators consisting of multiple driving units engaged with a sinusoidal transmission, termed a harmonic poly-actuator. Through theoretical analysis, it is obtained 1) conditions on the unit arrangement to eliminate their nonlinearity from the output force, 2) control algorithms for coordinating the multiple units to generate a commanded force with desired force-displacement characteristics, and 3) a method for compensating for output force ripples due to possible misalignment and heterogeneity of individual units. The control algorithms are implemented on a prototype harmonic poly-actuator with six units of PSAs. Experiments demonstrate the unique features of the poly-actuator exploiting inherent redundancy and harmonic properties of the system.

### CROSS-REFERENCE TO RELATED APPLICATIONS

This application is entitled to the benefit of Provisional Patent Application Ser. No. 62/159,432 filed May 11, 2015.

### BACKGROUND OF THE INVENTION

1. Field of the Invention

Certain embodiments of the present invention generally relate to a poly-actuator.

2. Description of the Related Art

Piezoelectric stack actuators (PSA), such as lead-zirconate-titanate (PZT), have several desirable properties including: a high bandwidth above 100 kHz, power density over 10⁸ W/m³, and efficiencies greater than 90%. For robotic and mechatronic applications, in particular, PSAs have two other major benefits: first, they are capacitive actuators and therefore, are highly efficient in maintaining large forces at a constant position. Second, they are back drivable, which can be essential for robots that physically interact with the environment. The major practical limitation is their limited strain, typically around 0.1%, that prevents PSAs from directly driving robotic and mechatronic systems.

In order to compensate for the limited stroke of the PSA, two types of leveraging approaches have been developed to greatly increase the effective displacement. One is internal leveraging where the PZT displacement is mechanically amplified. Most extensional piezoelectric devices, i.e. devices that utilize the d33 piezoelectric coefficient, rely on aligning the PSAs at a shallow angle with respect to each other and connecting them via rotational joints comprised of flexures. Typically their displacement amplification gain is 10 or less. In order to achieve larger amplification, these designs can be arranged in a nested architecture, or combined with other mechanical amplification mechanism.

The other type of leveraging is external leveraging where piezoelectric actuators perform cyclic motion which is converted to long-stroke linear or infinite stroke rotary motion. The most prevalent is ultrasonic motors (USM). These motors utilize a cyclic, high frequency input to produce continuous linear, rotary or complex multi-DOF motions. However, due to their reliance on friction, it is difficult to transmit a large force reliably under varying load conditions, which results in a low power density around 10⁴ W/m³. The lack of effective means to match impedance between the PSA and the load is another factor for the low power density.

Beyond USM, there are many ways of converting cyclic motion into a continuous output using PSAs. Inching motion was generated for a compliant leg walking robot, and repetitive wing or fin motion was used for a flying micro-robot and an underwater robot. This application is concerned with a hybrid type in which both internal and external leveraging methods are exploited. With use of the rolling contact buckling amplification mechanism, high gain amplification on the order of 100 in a single stage is obtained. This large gain of internal leveraging allows the PSAs to directly push gear teeth so that a long-stroke displacement may be determined kinematically by the number of teeth the PSA traveled, rather than relying on friction drive. Such a hybrid leveraging approach can be more efficient than USM in that a) a large force can be transmitted reliably, and b) shaping the gear tooth profile provides a means to effectively interface the actuator to the load, e.g. impedance matching.

The mechanism described above can be extended to one in which multiple PZT units are engaged with the output gear teeth so that a larger force can be generated collectively by the arrayed PZT units. See FIG. 1. This arrangement is referred to as a poly-actuator. Generally, a poly-actuator combines several simple units in series, parallel or both. Poly-actuators provide several salient features over a single actuator. First, the poly-actuator is a modular, scalable design; a variety of actuators with diverse maximum forces and speeds can be built by simply arranging a necessary number of units in series and parallel. Second, simplified individual control, for example ON-OFF control, can often times be sufficient; recruiting a different group of units to turn on, the output force or speed can be controlled. Finally, the redundancy within the actuator provides robustness to individual failure.

### SUMMARY OF THE INVENTION

It is a general object of certain embodiments of the present invention to provide a poly-actuator that substantially obviates one or more problems caused by the limitations and disadvantages of the related art.

Features and advantages of certain embodiments of the present invention will be presented in the description which follows, and in part will become apparent from the description and the accompanying drawings, or may be learned by practice of the invention according to the teachings provided in the description. Objects as well as other features and advantages of certain embodiments of the present invention will be realized and attained by the poly-actuator particularly pointed out in the specification in such full, clear, concise, and exact terms as to enable a person having ordinary skill in the art to practice the invention.

To achieve these and other advantages in accordance with the purpose of the invention, the invention provides a poly-actuator including an output unit having one or more cam portions, and a plurality of nonlinear reciprocating actuators each of which has a follower mechanism connected to the one or more cam portions, in which the cam portions are formed fey smooth periodically curved surfaces which guide rotational centers of the follower mechanisms along a sinusoidal trajectory with respect to a motion of the output unit, each of the nonlinear reciprocating actuators has nonlinearity in output force-displacement characteristics, the nonlinear reciprocating actuators are equally spaced in terms of a phase of the sinusoidal trajectory, a total distance obtained by multiplication of the number of the nonlinear reciprocating actuators and an equal interval between the nonlinear reciprocating actuators is equal to a multiple of a wave length of the sinusoidal trajectory, the equal interval is not equal to any multiple of the wave length, the output force has a nonlinear stiffness term including a k-th order term, if k is odd, orders of harmonic components of the sinusoidal trajectory in the output force consists of even numbers in 2 to k+1, and if k is even, orders of the harmonic components in the output force consists of odd numbers in 1 to k+1, and multiples of the number of the nonlinear reciprocating actuators do not match the orders of the harmonic components in the output force.

Other objects and further features of certain embodiments of the present invention will be apparent from the following detailed description when read in conjunction with the accompanying drawings.

### BRIEF DESCRIPTION OF THE DRAWINGS

FIG. 1 is a schematic of a PZT poly-actuator using hybrid internal-external leveraging: multiple PZT units with internal leveraging act in parallel on a single poly-actuator output rod. The Unit output travels in a sinusoidal path as the roller transmits the force to the output rod. Note the figure shows a single roller and track although more than one could be used for each Unit to transmit both an upward and downward force;

FIG. 2 is a simple diagram of the buckling amplification mechanism, demonstrating the bi-polar stroke. As the PSAs are energized, the output node deviates from the kinematic singularity in the center and “buckles” upwards or downwards;

FIG. 3 is a diagram illustrating a first example of a linear piezoelectric motor in one embodiment;

FIG. 4 is a block diagram illustrating an example of a control system in one embodiment;

FIG. 5 is a flow chart for explaining an example of a control process employing a control method in one embodiment;

FIG. 6 is a diagram illustrating a second example of the linear piezoelectric motor in one embodiment; and

FIG. 7 is a diagram illustrating a third example of the linear piezoelectric motor in one embodiment;

FIG. 8 is a schematic of the force transmission of the i^{th} Unit roller along the slope of the Transmission. The slope and the ratio of the two forces are directly related as defined in Eq. (4);

FIG. 9 is a schematic of the force transmission within a general poly-actuator architecture. The i^{th} Unit located at θᵢ=θ+θᵢ⁰ outputs a force fᵢ which is transformed by the sinusoidal Transmission to output Fᵢ. The total force F is the sum of the contribution from all n Units. The transmission ratio from fᵢ to Fᵢ is determined by the location and the geometry of the sinusoid, A and λ;

FIG. 10 is an output force-displacement profile given the input defined in (20a). The parameters C and φ are input control parameters. Note the stable regime surrounding the equilibrium point at

$$ϕ + \frac{π}{2}$$

is a passive property that does not requires any measurement or active control. Furthermore, if the poly-actuator is loaded by amount F_{load} the input can be used to tone the stiffness K̅ at the shifted equilibrium point lθ̅;

FIG. 11 is a plot showing two signals that both produce the same output. First, a sample input signal (solid line) utilizing the second mode of a system with 20 Units. Second, a signal (broken line) minimizing the sum of the squared inputs that combines the original with a sixth order signal;

FIG. 12 shows a table representing a general relationship between a k-th order term in a polynomial of a nonlinear stiffness term, a q-th order term in a polynomial of a input-induced force term, an L-th order harmonic component in an input u, harmonic components in an output force, and orders of remained harmonics in the output force;

FIG. 13 shows a table representing a concrete relationship between a k-th order term, in a polynomial of a nonlinear stiffness term, a q-th order term in a polynomial of a input-induced force term, an L-th order harmonic component in an input, harmonic components in an output force, and orders of remained harmonics in the output force;

FIG. 14 shows a CAD model of the harmonic PZT poly-actuator prototype;

FIG. 15 shows a table representing summary of parameters of the harmonic PZT poly-actuator;

FIG. 16 shows the measured output force over multiple wavelengths of the Transmission and at several commanded outputs. The output is shown with both ripple compensation (RC) off and on with the solid and dashed lines, respectively;

FIG. 17 shows spatial FFT of the output force ripple. The frequencies relate to the pitch of the gear and are affected by the discrepancies between Units, including position and stiffness; and

FIG. 18 shows the average output force over several wavelengths of the Transmission with ripple compensation versus a commanded force output F̅. The dashed line is the ideal slope of 1.

### DESCRIPTION OF THE PREFERRED EMBODIMENTS

In the following, certain embodiments of the present invention will be described with reference to the accompanying drawings.

### I. Introduction

In the current work, it is an object to further exploit the redundancy and modularity of poly-actuators to attain unique features that a single bulk actuator would not possess. The array of units can be coordinated or harmonized so that drawbacks of individual units may be compensated for For example, pronounced nonlinearities in force-displacement characteristics of individual units can be eliminated. The following presents theoretical analysis, design, and control synthesis for a) eliminating undesirable spatial nonlinearities, including singularities, b) coordinating the multiple units to generate desired force-displacement characteristics, c) exploiting the redundancy for optimizing around additional criteria, such as minimizing stored electrical energy, while producing the same output force, and d) compensating for force ripples due to misalignment and heterogeneity of individual units. These algorithms and methods exploit the harmonic nature of the arrayed units distributed along sinusoidal gear teeth.

Since the poly-actuator can attain a large stroke without sacrificing the capacitive properties or back drivability, it can he used in robots that specialize in human-robot interactions and frequently bear gravity loads. This includes assistive robots in a manufacturing environment, but could be expanded to all alternative to hydraulics and pneumatics in walking robots.

It is also presented a methodology for using harmonic analysis to simplify the modeling of the overall effective output of several Unit characteristics including: a) nonlinear stiffness relationships, b) linear dynamic parameters, c) generalized input signals, and d) errors. Furthermore, using the input relationships a feed-forward force controller is used in conjunction with the error analysis to globally compensate force ripple. The current work presents general and rigorous analysis of the harmonic properties of this type of poly-actuators, new control algorithms, and complete implementation and experimental evaluation.

### II. Theoretical Analysis

In this section, collective behaviors of a general class of actuator units involved in a poly-actuator will be analyzed. An individual actuator unit is referred to as a Driving Unit or simply a Unit. To provide a concrete concept, however, it is begun with a specific PZT amplification mechanism. FIG. 2 shows the schematic of a buckling displacement amplification mechanism used for a poly-actuator. When a voltage is applied to the PSAs, they expand, with displacement z, from the initial kinematical by singular position in the center, and rotate by angle Ω about the grounded rotational joints creating a vertical displacement y at the output node. This mechanism is able to produce a displacement amplification of two orders of magnitude within a single stage due to the immense instantaneous gain near the kinematic singularity as well as the ability to displace both upwards and downwards in bi-polar motion.

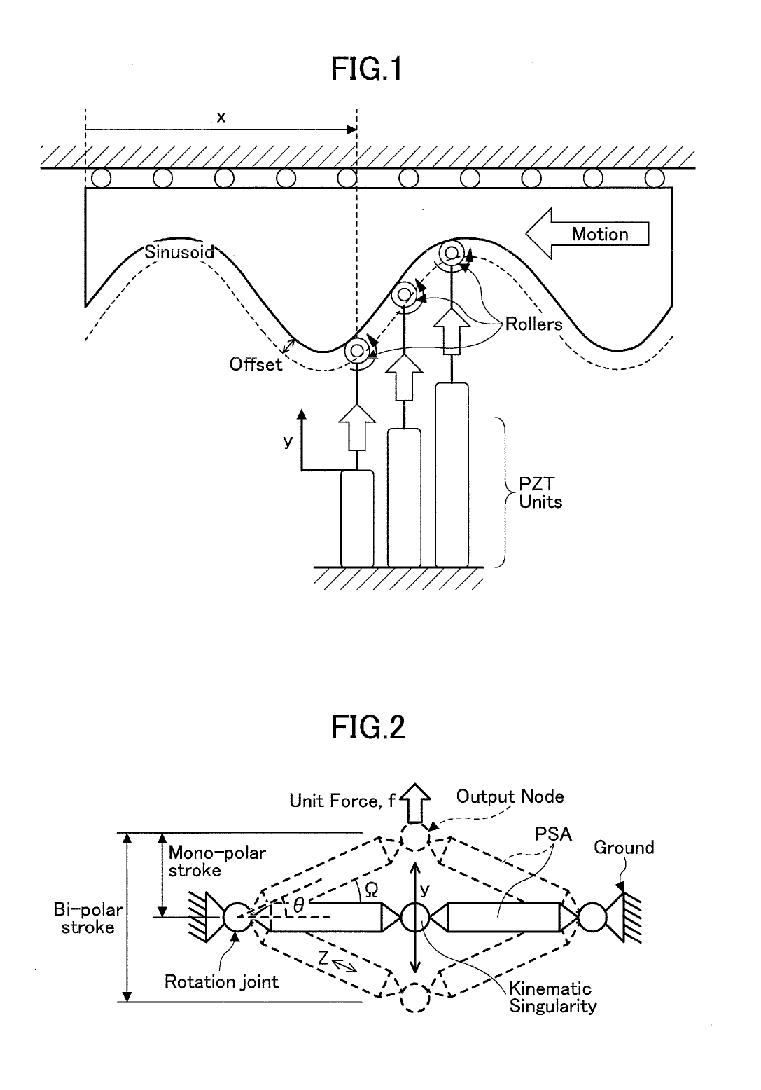

The PSAs with this buckling amplification mechanism exemplify the Driving Units within the poly-actuator, shown in FIG. 1. The vertical arrows show the displacement direction of the individual Units, whereas the horizontal arrow indicates the direction of the poly-actuator output.

The objective of this embodiment is to exploit salient features of poly-actuators consisting of multiple Driving Units. Two critical conditions for exploiting these features are: i) the force transmission property depending on the gear waveform is a sinusoid; and ii) the Units are equally spaced along the wavelength. It will be shown that, under these conditions, two features can be attained: first, it ensures there is never a point where all of the Units are in a kinematically singular configuration, and second, it balances each of the Units to regulate the total force generated by the multiple Driving Units despite the displacement-dependent output force of individual Units and their pronounced nonlinearity.

There are two types of kinematic singularities in a poly-actuator system: one due to the gear waveform, and the other from the singularity of each Units amplification mechanism. Within one full wavelength of the gear there are two peak points, top and bottom, that are a kinematic singularity because the slope of the gear is zero and, therefore, the constituent Unit cannot impose a force on the output. The Unit may also have a singular point, e.g. the center position of the buckling mechanism shown in FIG. 2. Therefore, it is possible to have more than 2 singular points present within one full wavelength.

In addition to the kinematic singularity, PSAs and other types of actuators using smart materials have nonlinear force-displacement characteristics. In the case of the buckling PZT actuators, the slope of the force-displacement curve, that is stiffness, varies depending on the displacement, exhibiting a pronounced nonlinearity. It will be shown that through the proper placement of the Driving Units the adverse effect of each Unit's nonlinear characteristics disappears and the output force becomes solely reliant on the input command and the gear location. This will also be proven in the following section.

Both of these properties are directly related to the sinusoidal waveform of the gear, and therefore yield the name “harmonic” poly-actuator.

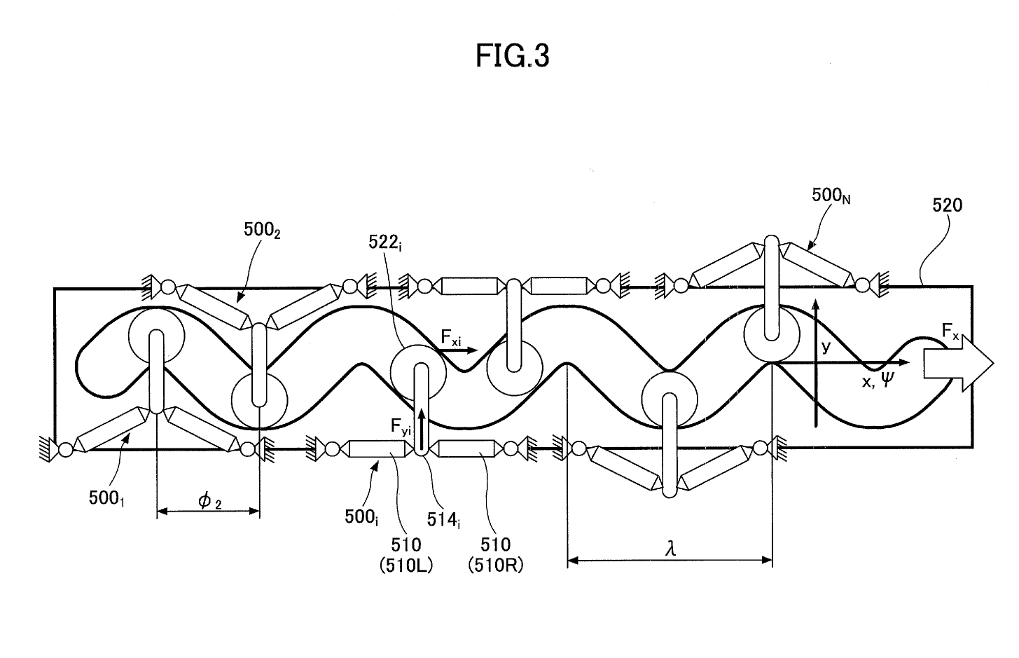

FIG. 3 is a diagram illustrating a first example of the linear piezoelectric motor in one embodiment. Further description of the linear piezoelectric motor is provided in Provisional Patent Application Ser. No. 61/808,279 filed Apr. 4, 2013, and in Japanese Patent Application Ser. No. 2014-74603 filed Mar. 31, 2014, which are incorporated by reference herein in their entirety. The linear piezoelectric motor includes a plurality of buckling actuators 500₁ through 500_{N} that are coupled to a PAS linear gear output rod 520 as an output unit having a sinusoidal gear (or cam) as illustrated in FIG. 3, and is driven by a phased bipolar actuator of the buckling actuators 500₁ through 500_{N}. The plurality of buckling actuators 500₁ through 500_{N} are arranged at a constant phase interval with respect to the gear (or cam) of the gear output rod 520 which converts outputs of the plurality of buckling actuators 500₁ through 500_{N} into a motor output.

A reciprocating motion of an output node 514ᵢ based on forces of piezoelectric elements 510 forming the buckling actuator 500ᵢ, applies a force F_{yi} perpendicular to a wavy groove of the gear output rod 520 via a follower 522ᵢ of the output node 514ᵢ. The gear (or cam) of the gear output rod 520 is shaped so that a motion trajectory of the output node 514i, which is an example of an engaging part of the buckling actuator 500ᵢ engaging the gear (or cam) of the gear output rod 520, has a sinusoidal wave shape with respect to the position of the gear output rod 520 along x-axis. A combination of the buckling actuators 500₁ through 500_{N} and the gear output rod 520 achieves high motor output efficiency during motion, while achieving low energy consumption during static holding due to its capacitive properties. Any force ripples or nonlinearity of a force Fₓᵢ transmitted to the gear output rod 520 from the buckling actuator 500ᵢ can be canceled out by phase control of the other buckling actuators. In essence, nodes of zero force transmission, and regions of varying force output can be combined in a constructive or destructive interference methodology to achieve a smooth net output force. Additionally, the plurality of buckling actuators 500₁ through 500_{N} working in parallel can boost a force output and provide redundancy and fault tolerance for a case in which a part of the piezoelectric elements 510, the buckling actuators 500, or force transmission components fails.

In FIG. 3, φᵢ (only illustrated for i=2) denotes a layout position of the i^{th} buckling actuator 500ᵢ, x denotes a gear position of the linear piezoelectric motor, y denotes an output displacement of the buckling actuator 500ᵢ, Ψ denotes an output position of the linear piezoelectric motor, λ denotes one cycle length of a motion trajectory of a rotational center of the follower 522ᵢ, and Fₓ denotes a continuous rightward gear force.

A rolling contact, buckling, displacement amplification mechanism may be used as the building block for the actuator architecture. This proposed amplification mechanism can transmit a high percentage of mechanical work between piezoelectric elements and external loads for the motor. This proposed amplification mechanism combined with the shaped gear output rod 520 allows for higher linear motor output efficiency during motion, while the capacitive properties provide low energy consumption during static holding.

In this embodiment, the rolling contact stiffness is improved to boost buckling actuator force output as well as the frame. Several rolling contact geometries are considered.

The secondary structural compliance arising from the frame structure may be improved by applying anisotropic materials which increase material stiffness along the load direction. This embodiment uses a primary load structure with a high modulus carbon fiber.

The modular poly-actuator architecture of the linear piezoelectric motor can provide the following functions. First, the use of the plurality of buckling actuators in parallel provides the ability for linear motor force output to foe controlled with high resolution. Any force ripples or nonlinearities transmitted to the gear output rod from the buckling actuators can be suppressed or cancelled out by phase control of additional buckling actuators. In essence, nodes of no force transmission, and regions of varying force output can he combined in a constructive or destructive interference methodology to achieve a smooth net output force. Second, the plurality of buckling actuators working in parallel boost instantaneous force output and provide redundancy and fault tolerance even when the piezoelectric elements, the buckling mechanism, or force transmission components fail.

To exploit the bipolar motion, a reciprocating displacement at the output node and a nonlinear force of the buckling amplification mechanism are required to transmit an output force to the gear output rod continuously. To minimize force ripples and to provide a smooth force output from the gear output rod against some external loads, a phase layout of the drive units with respect to the gear shapes on the gear output rod is required to be designed. Additionally, while gearing occurs in the buckling amplification mechanism, between the actuator force output and the buckling mechanism force output, an additional step of gearing is achievable by tuning the pitch length and amplitude of the gear output rod.

Because the bipolar motion of the buckling amplification mechanism is required to drive the gear output rod, the buckling actuator output direction needs to be controlled to actuate in a predetermined direction at the appropriate rod position. A kinematic singularity of each buckling mechanism, that is, a buckling singular point, is not deterministic by the buckling actuator itself, and thus, the predetermined direction or directionality must be controlled externally. The external control can be performed by a continuous contact engagement between the buckling mechanism output and the shaped surface (periodically curved surface) of the gear output rod. In regions away from the buckling singular point, the buckling mechanism motion deterministically drives the gear output rod. At the buckling singular point, the rod motion of the gear output rod forces the buckling mechanism with nearly zero impedance across the singularity. The buckling actuator output direction then becomes deterministic again.

Next, a description will be given of a force property of buckling actuators of the linear piezoelectric motor illustrated in FIG. 3. A general expression of the static output force Fₓ of the linear piezoelectric motor can be represented by the following formula (A), where i denotes the i^{th} buckling actuator 500ᵢ, N denotes a maximum number of the buckling actuators 500₁ through 500_{N}, Ψ denotes the output position of the linear piezoelectric motor described by a phase angle of the gear output rod 520, φᵢ denotes the layout position of the i^{th} buckling actuator 500ᵢ in the phase angle of gear output rod 520, Fₓᵢ denotes a contribution of the i^{th} buckling actuator 500ᵢ to the output force of the linear piezoelectric motor, G denotes the motion trajectory of the rotational center of the follower 522i of the buckling actuators 500 along the profile of the gear output rod a 520, R_{PAS} denotes the slope of the motion trajectory G with respect to the actual output position x of the linear piezoelectric motor, F_{yi} denotes the output force of the i^{th} buckling actuator 500ᵢ, uᵢ denotes the input to the i^{th} buckling actuator 500ᵢ, and λ denotes one cycle length of the motion trajectory G with the actual output position x.

$${F}_{x} {\sum }_{i = 1}^{N} {F}_{xi} ( ψ ) = {\sum }_{i = 1}^{N} {R}_{PAS} ( ψ + {φ}_{i} ) {F}_{yi} ( G ( ψ + {φ}_{i} ) , {u}_{i} ) \\ where x = \frac{λψ}{2 π} , {R}_{PAS} ( ψ + {φ}_{i} ) = \frac{d }{d x} G ( ψ + {φ}_{i} ) \qquad ( A )$$

Because the buckling actuators 500₁ through 500_{N} are connected in parallel through the gear output rod 520, all output forces of the buckling actuators 500₁ through 500_{N} are summed after the conversion by the gear output rod 520. The formula (A) above indicates that there are the following four freedoms a) through d) in designing the linear piezoelectric motor.

a) The property of the buckling actuators 500₁ through 500_{N};

b) The motion trajectory G determined by the gear shape of the gear output rod 520;

c) The layout of the buckling actuators 500₁ through 500_{N} with respect to the gear output rod 520; and

d) The input to the buckling actuators 500₁ through 500_{N}.

The formula (A) above also shows that all buckling actuators 500₁ through 500_{N} have interaction through the gear output rod 520. For example, when N is small, the interaction of the buckling actuators 500₁ through 500_{N} via the gear output rod 520 may have considerable effect. On the other hand, when N is large, the interaction between the each of the buckling actuators 500₁ through 500_{N} and the gear output rod 520 may be considered because the group of buckling actuators 500₁ through 500_{N} has an impedance much higher than that of each of the buckling actuators 500₁ through 500_{N}.

Next, a description will be given of geometric properties of the buckling actuators. Referring to the buckling actuator illustrated in FIG. 2 and assuming ideal solid base structures and ideal joints, an instantaneous displacement amplification ratio R_{B} with respect to a joint angle θ can be obtained from the following formula (B). L denotes a length of PSA.

$${R}_{B} = \frac{d y}{d z} = \frac{d y}{d θ} {( \frac{d z}{d θ} )}^{- 1} = \frac{L}{{cos}^{2} θ} {( \frac{L tan θ}{cos θ} )}^{- 1} = \frac{1}{sin θ} \\ where \{ \begin{matrix}y = L tan θ \\ z = L ( \frac{1}{cos θ} - 1 )\end{matrix} \qquad ( B )$$

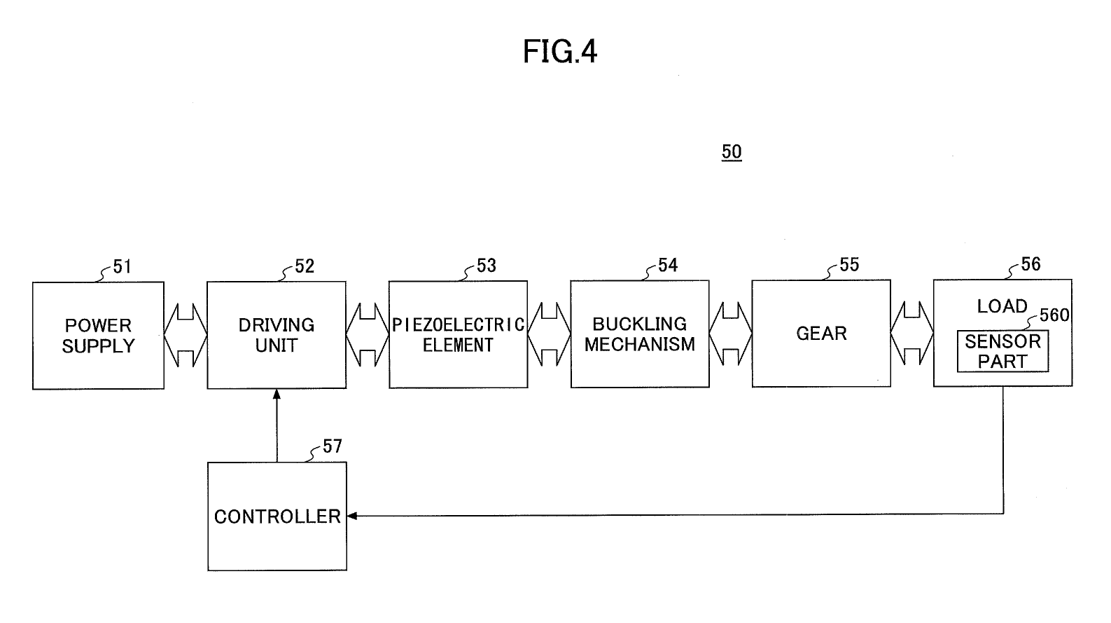

FIG. 4 is a block diagram illustrating an example of a control system in one embodiment. A control system 50 illustrated in FIG. 4 includes a power supply 51, a driving unit 52, a plurality of piezoelectric elements 53, a buckling mechanism 54, a gear 55, a load 56, and a controller 57. The driving unit 52 is powered by a power supply voltage from the power supply 51 and drives the piezoelectric elements 53. The piezoelectric elements 53 may correspond to the piezoelectric elements 510 (510R, 510L) of the linear piezoelectric motor described above, and may form the buckling actuators 500 described above. The driving unit 52 controls the voltage condition of each of the piezoelectric elements 53 based on a command from the controller 57, such as the ON and OFF states or the sinusoidal transition, for example.

The buckling mechanism 54 may include a plurality of buckling actuators having a compliance property, such as the buckling actuators 500 described above, for example. The plurality of buckling actuators are arranged at a constant phase interval with respect to the gear 55, and the phase interval cancels at least a part of the compliance property. In a case which a nonlinear component of the compliance property is approximated by a polynomial, the phase interval may cancel at least a part of harmonic components of the motor thrust generated by harmonic components caused by the nonlinear component. Hence, the driving unit 52 drives the buckling mechanism 54 by driving the piezoelectric elements 53 forming the buckling actuators of the buckling mechanism 54. The gear 55 may correspond to the linear gear output rod 520 described above, and convert outputs of the plurality of buckling actuators into a motor output. A motion trajectory of an engaging part of the plurality of buckling actuators engaging the gear 55 is shaped sinusoidal with respect to the gear 55 relying on the shape of the gear 55.

The driving unit 52, the piezoelectric elements 53, the buckling mechanism 54, and the gear 55 may form a linear piezoelectric motor. The load 56 may be a driving target that is driven by the gear 55 of the piezoelectric motor. The load 56 may include a part of the linear piezoelectric motor. The controller 57 may be formed by a processor, such as a CPU (Central Processing Unit).

In the example illustrated in FIG. 4, the load 56 includes a sensor part 560. However, the sensor part 560 may be provided with respect to the gear 55 to form a part of the linear piezoelectric motor. For example, the sensor part 560 may include a position sensor, a velocity sensor which detects a velocity of the gear 55 by known means, and a phase sensor which detects a gear phase angle of the gear 55 by known means. The configuration and the method of the velocity sensor is not limited to a particular type, as long as the velocity of the gear 55, and thus the velocity of the linear piezoelectric motor, is detectable from an output of the velocity sensor, or is observable from other types of sensors, for example, by derivation of signals from position sensors. The configuration of the phase sensor is not limited to a particular type, as long as the gear phase angle of the gear 55, and thus a rotational phase of the linear piezoelectric motor, is detectable from an output of the phase sensor, or is observable from other types of sensors, for example, by calculation of signals from position sensors.

The controller 57 may create a control signal for the driving unit 52 and generate a target thrust of the piezoelectric motor by the driving unit 52, based on a target velocity of the linear piezoelectric motor and the velocity of the linear piezoelectric motor received from the sensor part 560. The controller 57 may also generate a command of a target gear phase angle and a command of a target amplitude of the voltage which can be input to the piezoelectric elements, based on the gear phase angle of the gear 55 received from the sensor part 560. Hence, the controller 57 can obtain a first phase to adjust a voltage of each of the plurality of piezoelectric elements 53 of the buckling actuators forming the buckling mechanism 54 based on the target thrust, and a second phase with respect to the gear 55 for each of the plurality of piezoelectric elements 53 based on the target gear phase angle and the gear phase angle of the gear 55. Further, the controller 57 can compare the first and second phases to generate a voltage condition for the buckling actuators of the buckling mechanism 54, indicating a result of comparing the first and second phases.

The controller 57 can thus output the command to the driving unit 52 in order to control voltage inputs to the plurality of piezoelectric elements 53 based on the voltage condition. As a result, the driving unit 52 inputs a voltage to the plurality of piezoelectric elements 53. The voltage depends on a corresponding phase angle of the gear 55 and having a waveform including a sinusoidal wave component, for example. This voltage input to the plurality of piezoelectric elements 53 may be determined to adjust the motor thrust according to an amplitude of the sinusoidal component and/or a phase difference between a shape of the gear 55 and the waveform. Accordingly, each buckling actuator of the buckling mechanism 54 is driven to output a buckling force, and each buckling force is then converted depending on the slope of the gear 55 in each gear phase. The integrated force of the buckling actuators of the buckling mechanism 54 drives the gear 55 and can thus drive the load 56.

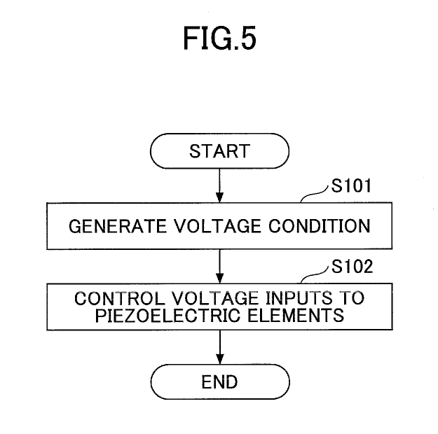

FIG. 5 is a flow chart for explaining an example of a control process employing a control method in one embodiment. A control process illustrated in FIG. 5 controls a linear piezoelectric motor that includes a plurality of buckling actuators having a compliance property and including a plurality of piezoelectric elements, and a gear to convert outputs of the plurality of buckling actuators into a motor output. The control process may be performed by the control system 50 illustrated in FIG. 4, for example.

In step S101 illustrated in FIG. 5, the controller 57 generates a voltage condition for the buckling actuators of the buckling mechanism 54, in the manner described above in conjunction with FIG. 4. In step S102, the controller 57 outputs a command to the driving unit 52 in order to control voltage inputs to the plurality of piezoelectric elements 53 based on the voltage condition. More particularly, the controller 57 controls the driving unit 52 to input a voltage to the plurality of piezoelectric elements 53. The voltage depends on a corresponding phase angle of the gear 55 and having a waveform including a sinusoidal wave component, for example. This voltage input to the plurality of piezoelectric elements 53 may be determined to adjust the motor thrust according to an amplitude of the waveform and/or a phase difference between a shape of the gear 55 and the waveform. Hence, each buckling actuator of the buckling mechanism 54 is driven to output a buckling force, and each buckling force is then converted depending on the slope of the gear 55 in each gear phase. The integrated force of the buckling actuators of the buckling mechanism 54 drives the gear 55 and can thus drive the load 56.

The controller 57 can control the driving unit 52 to input to the plurality of piezoelectric elements 53 a voltage depending on a corresponding phase angle of the gear 55 and having a waveform including a square wave component, for example.

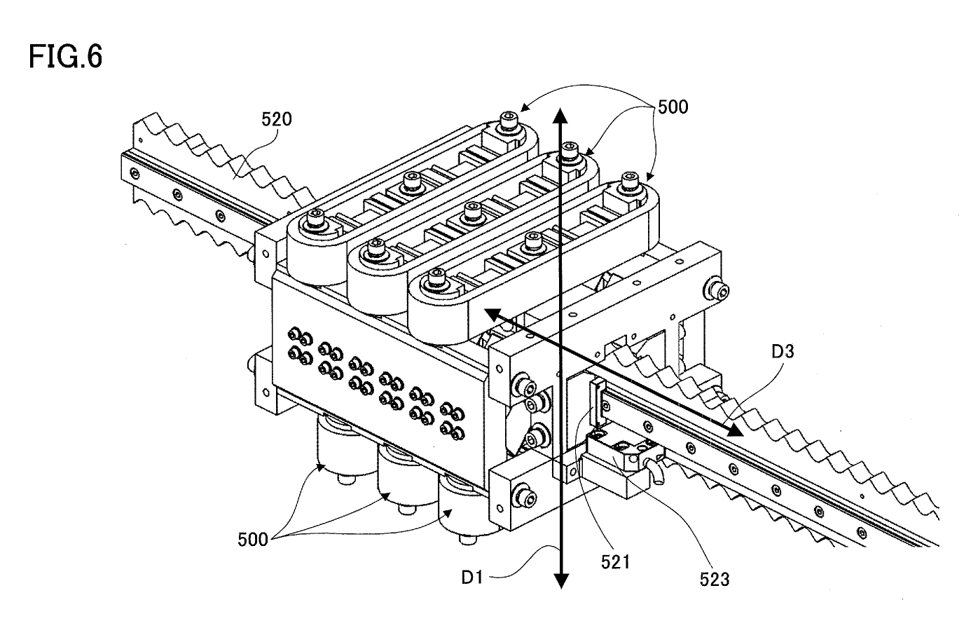

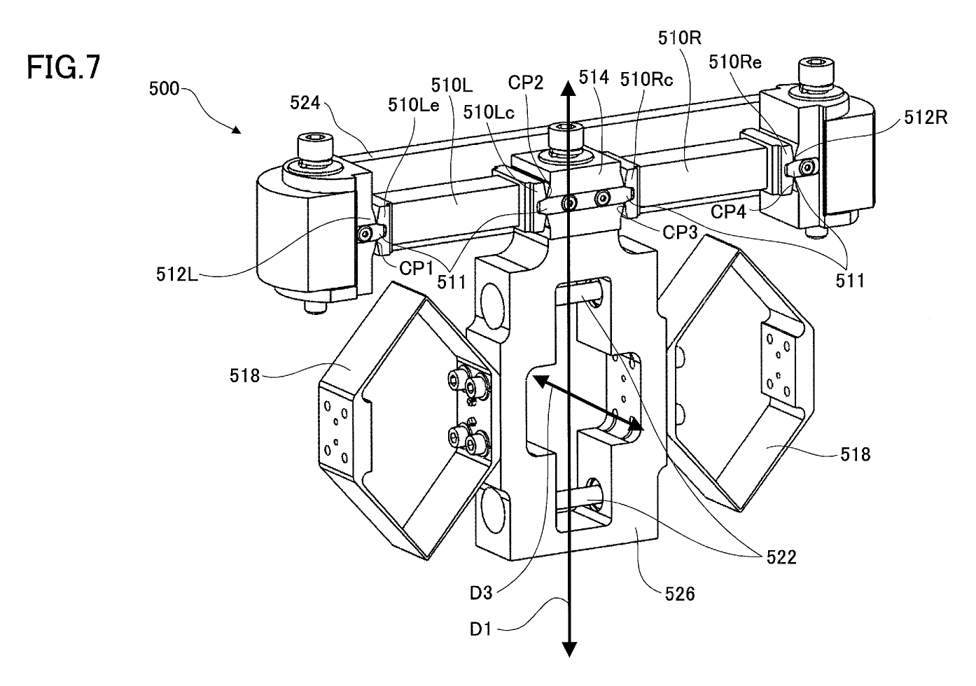

The control system and the control method described above may similarly drive and control a piezoelectric motor (or actuator) other than that illustrated in FIG. 3, for example. Examples of the linear piezoelectric motor may include the following described in conjunction with FIGS. 6 and 7.

FIG. 6 is a diagram illustrating a second example of the linear piezoelectric motor in one embodiment. The linear piezoelectric motor includes a plurality of buckling actuators 500 that are coupled to a linear gear output rod 520 having a modified sinusoidal gear as illustrated in FIG. 6, and is driven by a phased bipolar actuator of the buckling actuators 500.

A reciprocating motion of an output node in a direction D1 based on forces of piezoelectric elements forming the buckling actuators 500 applies a force perpendicular to a wavy groove of the gear output rod 520 via a follower. Hence, linear piezoelectric motor or the gear output rod 520 moves in an output direction D3 under guidance of a linear guide 521, and the motor displacement is detected by known means using a sensor 523.

A maximum rated velocity vₓₘₐₓ may be set by considering the thermal property of piezoelectric elements. The voltage and frequency affect the amount of power loss in the buckling actuators 500 and the thermal excitation. Materials used for the piezoelectric elements lose piezoelectricity above their Curie temperatures. For these reasons, a practical restriction on the operation condition of the linear piezoelectric motor may be determined by considering the temperature.

The wave length of the PAS, λ, may be determined by considering the contact stress between the PAS and followers driven by the buckling actuators 500. Because the maximum contact stress occurs at the tip of the PAS tooth, the radius of curvature of the joints are preferably more than a certain radius and made of a hardened tool steel, for example.

FIG. 7 is a diagram illustrating a third example of the linear piezoelectric motor in one embodiment. The linear piezoelectric motor includes a buckling actuator 500. The buckling actuator 500 includes a frame 524, and piezoelectric elements 510R and 510L. The piezoelectric element 510R is connected between a side block 512R on the frame 524 and an output part 514 via first and second rotary joints, respectively. The first rotary joint includes a pivotally supported member 510Re supported by a support 511 on the side block 512R, and the second rotary joint includes a pivotally supported member 510Rc supported on the output part 514. Similarly, the piezoelectric element 510L is connected between a side block 512L on the frame 524 and the output part 514 via third and fourth rotary joints, respectively. The third rotary joint includes a pivotally supported member S10Le supported by a support 511 on the side block 512L, and the fourth rotary joint includes a pivotally supported member 510Lc supported on the output part 514. In FIG. 7, CP1 and CP2 denote contact positions of the piezoelectric element 510L, and CP3 and CP4 denote contact positions of the piezoelectric element 510R.

The output part 514 includes a frame 526 having an opening in which a pair of cylindrical followers 522 is provided. A PCS (Preload Compensation Spring) 518 having a hexagonal frame shape is provided on both sides of the frame 526. Each PCS 518 may be fixed to a support (not illustrated) or the like. A linear gear output rod (not illustrated) penetrates the opening in the frame 526 of the output part 514, and engages the followers 522. A reciprocating motion of the output part in the direction D1 based on forces of the piezoelectric elements 510R and 510L forming the buckling actuator 500 applies a force perpendicular to a wavy groove of the gear output rod via the followers 522. Hence, linear piezoelectric motor or the gear output rod moves in the output direction D3.

Although the embodiment described above is applied to a linear type actuator, the embodiment may similarly be applied to a rotation type actuator.

### A. Formation of Unit Properties and Output Force

The fundamental property of individual actuator Units is described by force-displacement characteristics:

f=g(y)+b(y)u (1)

where f is the Unit force, y is the Unit displacement and u is the input. The Unit force has an input-induced force term b(y)u having a displacement dependent coupling function b(y) as well as a nonlinear stiffness function g(y). As described later, piezoelectric actuators and other capacitive actuators possess this type of force-displacement characteristics. Both functions, g(y) and b(y), are assumed to be smooth continuous functions and, more specifically, to be described generally as finite polynomials:

$$\begin{matrix}g ( y ) = {\sum }_{k = 0}^{m} {h}_{k} {y}^{k} & ( 2 ) \\ b ( y ) = {\sum }_{q = 0}^{p} {η}_{q} {y}^{q} & ( 3 )\end{matrix}$$

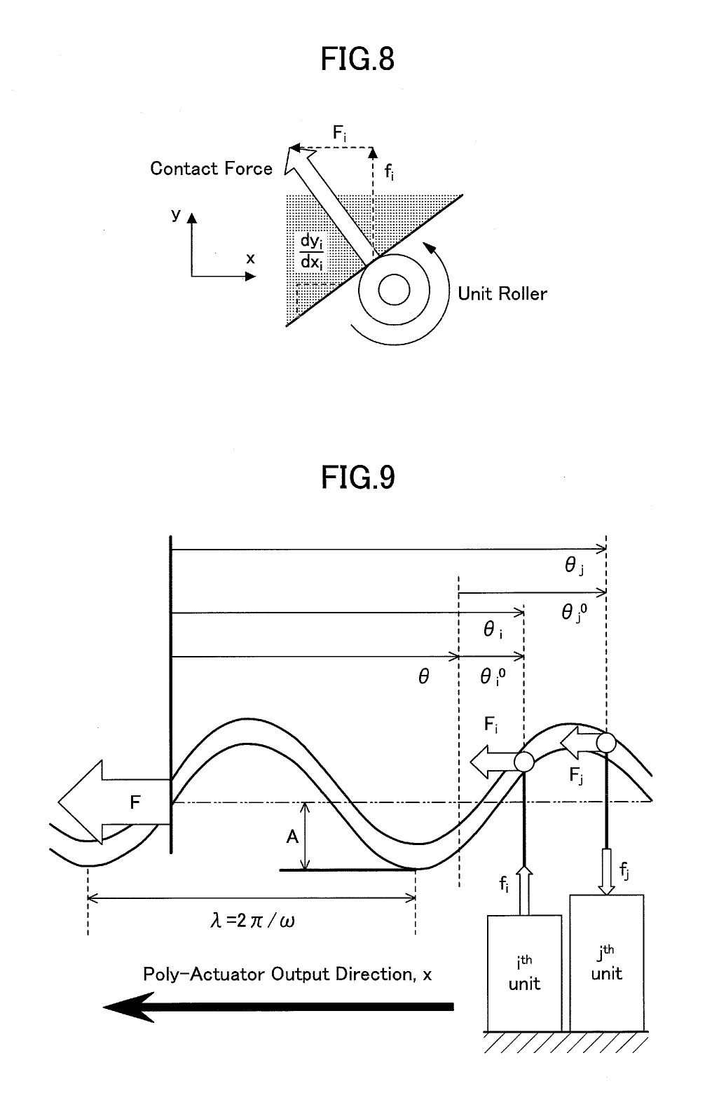

The bandwidth of the Unit, on the order of 50 Hz, is significantly less than that of PSA upwards of 10 kHz. Therefore, it is apt to model the PSA as a spring in parallel with a force source controlled by the input voltage. Each Unit is engaged with a train of gear teeth at a particular location, as previously shown in FIG. 1. The mechanism that aggregates the forces of individual Units into a single output is referred to as a Parallel Transmission, or simply a Transmission, in this application. The force of the i^{th} Unit fᵢ is transmitted to the output Fᵢ through the sloped surface of the Transmission as opposed to relying on friction as shown in FIG. 8.

The fundamental property of individual actuator Units is also described by a general output force characteristic:

f=g(y,u) (1)′

where y is a vector containing the Unit displacement y and its derivatives \dot{y},ÿ, etc. and u is the input. In general, the force function g could be nonlinear and as complex as necessary.

The contribution to the output force from the i^{th} Unit Fᵢ is, therefore a function of the Unit force fᵢ and the instantaneous slope of the Transmission at the Unit position

$$\frac{d {y}_{i}}{d {x}_{i}} .$$

Each Unit has an individual position along the Transmission xᵢ, vertical position yᵢ and output force fᵢ, but it is assumed that all of the coefficients in (6) are consistent among the Units. The force of the i^{th} Unit transmitted to the output is given by:

$${F}_{i} = - {f}_{i} \frac{d {y}_{i}}{d {x}_{i}} \qquad ( 4 )$$

where x is the poly-actuator output displacement, and

$$\frac{d y}{d x}$$

is the slope of the Transmission waveform at position x.

Subsequently, the aggregate output force is then given by:

$$F = {\sum }_{i = 1}^{n} {F}_{i} \qquad ( 5 )$$

A particular class of Transmission that possesses useful features is a sinusoidal waveform:

$$y = A sin ω x \\ \frac{d y}{d x} = A ω cos ω x \qquad ( 6 )$$

where A and ω are the amplitude and spatial frequency of the sinusoid, respectively. Let λ be the wavelength of the sinusoid shown in FIG. 9. The spatial frequency is then given by

$$ω = \frac{2 π}{λ} .$$

### Using

the spatial frequency, the location along the sinusoid wavelength is represented by phase angle: θ=ωx. Then, the i^{th} Unit force is given by:

Fᵢ=F_{i,g}+F_{i,b} (7a)

F_{i,g}=g(Asin θᵢ)·Aω cos θᵢ (7b)

F_{i,b}=b(Asin θᵢ)uᵢ·Aω cos θᵢ (7c)

where θᵢ uᵢ are phase position and input of the i^{th} Unit, respectively.

The location along the sinusoid wavelength is also represented by phase angle: θ=ωx,\dot{θ}=ω\dot{x},\ddot{θ}=ω\ddot{x}. The velocity and acceleration of the Unit can also be expressed in terms of the position, velocity and acceleration of the output.

$$\dot{y} = \frac{d y}{d x} \dot{x} = A \dot{θ} cos θ \\ \ddot{y} = \frac{d y}{d x} \ddot{x} + \frac{{d}^{2} y}{d {x}^{2}} {\dot{x}}^{2} = A ( \ddot{θ} cos θ - {\dot{θ}}^{2} sin θ ) \qquad {( 6 )}^{′}$$

Note that the output velocity and the acceleration of the output, \dot{x} and \ddot{x} respectively, are independent of the individual unit, i.e. \dot{x}₁=\dot{x}₂=\dot{x}ᵢ. This analysis aims to take advantage of the harmonic properties of the Unit force in the direction of the output Fᵢ. The methodology presented applies generally, but for the purpose of this embodiment, it will be considered a function that contains three distinct terms: 1) a nonlinear stiffness term gₛ, 2) a dynamic term g_{d}, and 3) an input term coupled with the Unit position gᵤ. As described later, piezoelectric actuators and other capacitive actuators possess this type of output force characteristic.

$$\begin{matrix}f = {g}_{s} ( y ) + {g}_{d} ( \dot{y} , \ddot{y} ) + {g}_{u} ( y , u ) & {( 6 a )}^{′} \\ {g}_{s} ( y ) = {\sum }_{k = 0}^{m} {h}_{k} {y}^{k} & {( 6 b )}^{′} \\ {g}_{d} ( \dot{y} , \ddot{y} ) = β \dot{y} + μ \ddot{y} & {( 6 c )}^{′} \\ {g}_{s} ( y , u ) = u {\sum }_{q = 0}^{p} {η}_{q} {y}^{q} & {( 6 d )}^{′}\end{matrix}$$

Therefore, the force in the direction of the output of the i^{th} Unit is given by:

Fᵢ=F_{i,s}+F_{i,d}+F_{i,u} (7a)′

F_{i,s}=gₛ(Asin θᵢ)·Aω cos θᵢ (7b)′

F_{i,d}=g_{d}(A\dot{θ} cos θᵢ, A(\ddot{θ} cos θᵢ−\dot{θ} ² sin θᵢ))·Aω cos θᵢ (7c)′

F_{i,u}=gᵤ(Asin θᵢ, uᵢ)·Aω cos θᵢ (7d)′

where θᵢ and uᵢ are phase position and input of the i^{th} Unit, respectively.

### B. Elimination of the Effect of Non-Linear Stiffness

The poly-actuator with a sinusoidal Transmission can possess useful properties if harmonics are exploited by coordinating the multiple Units. Specifically, the nonlinear stiffness of each Unit can be eliminated from the output force. If the n Units are spatially distributed with a particular spacing, the force generated by the nonlinear stiffness of one Unit can be balanced by another Unit. The following Proposition describes this useful property.

Proposition 1: In the poly-actuator described by (1)-(7), the forces associated with the nonlinear stiffness of each Unit balance, so that the output force F does not depend on the internal nonlinear properties of the individual Units:

$$\begin{matrix}{\sum }_{i = 1}^{n} {F}_{i , g} = 0 , ∀ θ & ( 8 ) \\ {\sum }_{i = 1}^{n} {F}_{i , s} = 0 , ∀ θ & {( 8 )}^{′}\end{matrix}$$

when the following sufficient conditions are met:

θᵢ⁰kn=2π,4π, . . . , 0<k≦m (9)

θᵢ⁹kn=2π, 4π, . . . ∀k:αₖ≠0 or bₖ≠0 (9)′

θᵢ⁰k≠0,2π,4π, . . . ,0<k≦m (10)

θᵢ⁰k≠0,2π, 4π, . . . ∀k:αₖ≠0 or bₖ≠0 (10)′

θᵢ⁰ is the phase position of the i^{th} Unit relative to the position of the output rod measured in phase angle, θᵢ⁰=θᵢ−θ, as shown in FIG. 9.

Proof: For the purpose of analysis, it is useful to rewrite the transformed component of a single Unit's nonlinear stiffness to the output force, F_{i,g} in (7b), as a summation of several harmonics, which allows for convenient analytical methods to be applied. The new expression is equivalent without any loss in generality or requiring any additional assumptions.

$$\begin{matrix}\begin{matrix}{F}_{i , g} = {\sum }_{k = 0}^{m} {h}_{k} {A}^{k + 1} {ωsin}^{k} {θ}_{i} cos {θ}_{i} \\ = {\sum }_{k = 1}^{m + 1} [ {a}_{k} cos k {θ}_{i} + {b}_{k} sin k {θ}_{i} ]\end{matrix} & ( 11 ) \\ \begin{matrix}{F}_{i , s} = {\sum }_{k = 0}^{m} {h}_{k} {A}^{k + 1} {ωsin}^{k} {θ}_{i} cos {θ}_{i} \\ = {\sum }_{k = 1}^{m + 1} [ {a}_{k} cos k {θ}_{i} + {b}_{k} sin k {θ}_{i} ]\end{matrix} & {( 11 )}^{′}\end{matrix}$$

where aₖ and bₖ (k=1, . . . , m+1) are coefficients determined by taking the Fourier transform of F_{i,g}.
It is desired, to show that

$${\sum }_{i = 1}^{n} {F}_{i , s} = 0 or ( {\sum }_{i = 1}^{n} {F}_{i , s} = 0 )$$

by proving each term in (11) summed over i=1, . . . , n is equal to zero for all output phase positions θ. For an arbitrary k, replacing θᵢ by θ+θᵢ⁰ in (11), the following expression can be attained:

$${\sum }_{i = 1}^{n} [ {a}_{k} cos k {θ}_{i} + {b}_{k} sin k {θ}_{i} ] = {\sum }_{i = 1}^{n} [ cos k θ ( {a}_{k} cos k {θ}_{i}^{0} + {b}_{k} sin k {θ}_{i}^{0} ) ] + {\sum }_{i = 1}^{n} [ sin k θ ( {b}_{k} cos k {θ}_{i}^{0} - {a}_{k} sin k {θ}_{i}^{0} ) ] \qquad ( 12 )$$

### Therefore, if

$${\sum }_{i = 1}^{n} {e}^{j k {θ}_{i}^{0}} = {\sum }_{i = 1}^{n} ( cos k {θ}_{i}^{ } + jsin k {θ}_{i}^{0} ) = 0$$

where j is the imaginary number, then the expression in (12) is zero for all output phase positions θ. If this can be shown for all k, then

$${\sum }_{i = 1}^{n} {F}_{i , g} = 0 or ( {\sum }_{i = 1}^{n} {F}_{i , x} = 0 ) .$$

If the relative phase position θᵢ⁰ is a linear function with the Unit index i, then the expression can be expanded using a geometric series:

$$If {e}^{2 π j \frac{k}{n}} \neq 1 \\ {\sum }_{i = 1}^{n} {e}^{j k {θ}_{i}^{0}} = \frac{[ 1 - {( {e}^{2 πj \frac{k}{n}} )}^{n} ] {e}^{2 π j \frac{k}{n}}}{1 - {e}^{2 π j \frac{k}{n}}} = 0 \qquad ( 13 )$$

The conditions (9), (9)′ and (10), (10)′ ensure that (13) is always true, then the poly-actuator output force F is entirely independent of the nonlinear stiffness term g(yᵢ) and solely relies on the sum of the terms containing the inputs, ΣF_{i,b} or ΣF_{i,u}.

### Remark 1:

A sufficient condition that satisfies both (9) and (10) is if enough Units are spread equally along one period of the Transmission:

$$\begin{matrix}{θ}_{i}^{0} = 2 π \frac{i}{n} & ( 14 a ) \\ n > m + 1 & ( 14 b )\end{matrix}$$

For the purpose of the analysis in this embodiment, these conditions will be assumed for any additional derivations. However, given a specific application, it could foe beneficial to deviate from these conditions. For example, the minimum number of Units to balance the nonlinear terms can be significantly reduced if the specifics of the system are exploited. Consider a case where the nonlinear stiffness function g(y) is purely an odd function. If so, there is no difference between the output force at an arbitrary position from a single Unit and the output force from a single Unit shifted by π radians F_{i,g}(θᵢ)=F_{i,g}(θᵢ+π). If there is even number of actuators n and the arrangement is as described in (14a), then each Unit

$$i > \frac{n}{2}$$

has another Unit that always produces exactly the same force. This is equivalent, then to having half the number of Units over half a cycle:

$$\begin{matrix}{n}^{′} = \frac{n}{2} & ( 15 a ) \\ {θ}_{i}^{0} = π \frac{i}{{n}^{′}} & ( 15 b )\end{matrix}$$

Therefore, if g(y) is odd, n is even, and the conditions in (14) are satisfied, then (15) must also be a balanced configuration.

### C. Transmission of Linear Dynamic Parameters

Similar to the stiffness function, the dynamics of the Units can be balanced to remove the oscillation due to the repetitive vertical Unit motion and can be modeled as a whole as linear parameters.

Proposition 1A: If the dynamic properties associated with damping, β, and mass, μ, are linear as defined in (6c)′ and the arrangement of Units is described by (14a) where the number of Units n is greater than 2, then the output also has linear dynamics associated with an effective damping and mass B_{eff} and M_{eff} respectively.

Proof:

The dynamic force in the direction of the output from a single Unit is defined in (7c)′. This force can be separated into a contribution from the damping and mass, F_{i,B} and F_{i,M}.

$$\begin{matrix}{F}_{i , d} = {F}_{i , B} + {F}_{i , M} & {( 15 a )}^{′} \\ \begin{matrix}{F}_{i , B} = β {A}^{2} ω \dot{θ} {cos}^{2} {θ}_{i} \\ = \frac{β {A}^{2} ω}{2} \dot{θ} ( 1 + cos 2 {θ}_{i} )\end{matrix} & {( 15 b )}^{′} \\ \begin{matrix}{F}_{i , M} = μ {A}^{2} ω ( \ddot{θ} {cos}^{2} {θ}_{i} - {\dot{θ}}^{2} sin {θ}_{i} cos {θ}_{i} ) \\ = \frac{μ {A}^{2} ω}{2} [ \ddot{θ} ( 1 + cos 2 {θ}_{i} ) - {\dot{θ}}^{2} sin 2 {θ}_{i} ]\end{matrix} & {( 15 c )}^{′}\end{matrix}$$

Summing the damping force from a single Unit F_{i,B} and repeating a process similar to the stiffness function, the individual phase positions θᵢ can be replaced with the sum of the global and relative phase position θ+θᵢ⁰.

$$\begin{matrix}{F}_{B} = {\sum }_{i = 1}^{n} {F}_{i , B} \\ = \frac{{bA}^{2} ω}{2} \dot{θ} ( {\sum }_{i = 1}^{n} 1 + {\sum }_{i = 1}^{n} cos 2 {θ}_{i} ) \\ = \frac{{bA}^{2} ω}{2} \dot{θ} [ n + cos 2 θ {\sum }_{i = 1}^{n} cos 2 {θ}_{i}^{0} - sin 2 θ {\sum }_{i = 1}^{n} sin 2 {θ}_{i}^{0} ]\end{matrix} \qquad {( 16 )}^{′}$$

Given that there are more than two Units n>2 and they are arranged, equally along one period of the Transmission (14a), then the terms containing cos 2θᵢ⁰ and sin 2θᵢ⁰ sum to zero. Therefore, the damping force is:

$${F}_{B} = \frac{{bA}^{2} ω n}{2} \dot{θ} = {B}_{eff} \dot{θ} \qquad {( 17 )}^{′}$$

Similarly, for the inertial term F_{i,M}:

$$\begin{matrix}{F}_{M} = {\sum }_{i = 1}^{n} {F}_{i , M} \\ = \frac{μ {A}^{2} ω}{2} ( \ddot{θ} {\sum }_{i = 1}^{n} ( 1 + \ddot{θ} cos 2 {θ}_{i} ) - {\dot{θ}}^{2} {\sum }_{i = 1}^{n} sin 2 {θ}_{i} ) \\ = \frac{μ {A}^{2} ω}{2} [ \begin{matrix}n \ddot{θ} + ( \ddot{θ} cos 2 θ - {\dot{θ}}^{2} sin 2 θ ) {\sum }_{i = 1}^{n} cos 2 {θ}_{i}^{0} - \\ ( \ddot{θ} sin 2 θ + {\dot{θ}}^{2} cos 2 θ ) {\sum }_{i = 1}^{n} sin 2 {θ}_{i}^{0}\end{matrix} ]\end{matrix} \qquad {( 18 )}^{′}$$

Once again, the terms containing cos 2θᵢ⁰ and sin 2θᵢ⁰ sum to zero given the sufficient conditions, therefore, the inertial force is:

$${F}_{M} = \frac{μ {A}^{2} ω n}{2} \ddot{θ} = {M}_{eff} \ddot{θ} \qquad {( 19 )}^{′}$$

Between the elimination of the stiffness function gₛ and the passive transmission of the linear dynamic parameters μ and β, the harmonic properties of the output due to several Units placed along the sinusoidal Transmission provides a simple architecture for the poly-actuator. The harmonic analysis used to model the transmission of force can also be applied to more complicated nonlinearities, including hysteresis, to determine the overall effect on the output. Once a model can be summarized and measured, the undesired effects can foe addressed through the input as will be shown in subsequent sections.

### D. Single Frequency Sinusoidal Inputs

The equation for output force from a single Unit containing the input terms F_{i,b}, (7c), can be expanded to:

$$\begin{matrix}\begin{matrix}{F}_{i , b} = ( {\sum }_{q = 0}^{p} {η}_{q} {A}^{q + 1} {ωsin}^{q} {θ}_{i} cos {θ}_{i} ) {u}_{i} \\ = ( {\sum }_{q = 1}^{p + 1} [ {c}_{q} cos q {θ}_{i} + {d}_{q} sin q {θ}_{i} ] ) {u}_{i}\end{matrix} & ( 16 ) \\ \begin{matrix}{F}_{i , u} = ( {\sum }_{q = 0}^{p} {η}_{q} {A}^{q + 1} {ωsin}^{q} {θ}_{i} cos {θ}_{i} ) {u}_{i} \\ = ( {\sum }_{q = 1}^{p + 1} [ {c}_{q} cos q {θ}_{i} + {d}_{q} sin q {θ}_{i} ] ) {u}_{i}\end{matrix} & {( 16 )}^{″}\end{matrix}$$

where the coefficients c_{q}and d_{q} are given by:

$$\begin{matrix}{c}_{q} = \frac{A ω}{π} {\int }_{0}^{2 π} b ( A sin τ ) cos τ cos q τ d τ & ( 17 a ) \\ {d}_{q} = \frac{A ω}{π} {\int }_{0}^{2 π} b ( A sin τ ) cos τ sin q τ d τ & ( 17 b )\end{matrix}$$

Given that the sufficient conditions for Proposition 1 (14) are satisfied, the output force F relies solely on terms containing the input F_{b},i.e. the summation of (16).

$$F = {F}_{b} = {\sum }_{i = 1}^{n} [ {u}_{i} {\sum }_{q = 1}^{p + 1} [ {c}_{q} cos q {θ}_{i} + {d}_{q} sin q {θ}_{i} ] ] \qquad ( 18 )$$

Replacing θᵢ with θ+θᵢ⁰ yields:

$${F}_{b} = {\sum }_{q = 1}^{p + 1} [ cos q θ {\sum }_{i = 1}^{n} {u}_{i} ( {c}_{q} cos q {θ}_{i}^{0} + {d}_{q} sin q {θ}_{i}^{0} ) + sin q θ {\sum }_{i = 1}^{n} {u}_{i} ( {d}_{q} cos q {θ}_{i}^{0} - {c}_{q} sin q {θ}_{i}^{0} ) ] \qquad ( 19 )$$

Each Unit input u, is multiplied by a term containing the position θ=ωx, either cos qθ or sin qθ. Furthermore, the series of inputs u₁, . . . , uₙ are convoluted with a series of harmonics θᵢ⁰, 2θᵢ⁰, . . . , (p+1)θᵢ⁰ through the terms containing cos qθᵢ⁰ and sin qθᵢ⁰. Therefore, if the input uᵢ is constructed as a sinusoidal function of the l^{th} harmonic: lθ where 1≦l≦p+1 and there are enough Units n, then the output force F_{b} does not contain any harmonics other than the l^{th} one.

Proposition 2: The Unit inputs are given as phased sample points of the l^{th} harmonic function in the following form:

uᵢ=uᵢ(θᵢ⁰)=Uₗcos(lθᵢ^{0-α}ₗ) (20a)

1≦i≦n (20b)

1≦l≦p+1 (20c)

where Uₗ and αₗ are the input amplitude and input phase shift of the i^{th} mode, and θᵢ⁰ is the relative position of the Unit. If two sufficient conditions are met:

cₗ≠0 or dₗ≠0 (21)

and:

n>l+p+1 (22)

then the output force F is a sinusoidal function of the same phase angle lθ and all the other modes vanish:

F=Ccos(lθ−φ) (23)

Proof: This property relies on the orthogonality of sinusoidal modes. The series of Unit inputs can be written as:

uᵢ=u(θᵢ⁰)=λₛsinlθᵢ⁰+λ_{c}coslθᵢ⁰ (24)

where Uₗ=\sqrt{λₛ²+λ_{c}²} and

$$tan {α}_{l} = \frac{{λ}_{s}}{{λ}_{c}} .$$

Substituting (24) into (19) yields products of cos qθᵢ⁰, sin qθᵢ⁰ and cos lθᵢ⁰, sin lθᵢ⁰. The summation of these products over i becomes zero unless q=l under the condition (22). See (25) for example.

$$\begin{matrix}{\sum }_{i = 1}^{n} cos q {θ}_{i}^{0} \cdot cos l {θ}_{i}^{0} = \frac{1}{2} {\sum }_{i = 1}^{n} [ cos ( q + l ) {θ}_{i}^{0} + cos ( q - l ) {θ}_{i}^{0} ] \\ = \{ \begin{matrix}0 \text{:} q \neq l \\ \frac{n}{2} \text{:} q = l\end{matrix}\end{matrix} \qquad ( 25 )$$

Note that (13) was used again given the conditions in (14a) and (22). Substituting these into (19), the following expression can be obtained:

$$\begin{matrix}\begin{matrix}F = {F}_{b} \\ = \frac{n}{2} [ {λ}_{c} ( {c}_{l} cos l θ + {d}_{l} sin l θ ) + {λ}_{s} ( {d}_{l} cos θ - {c}_{l} sin l θ ) ] \\ = C cos ( l θ - φ )\end{matrix} & ( 26 ) \\ where C = \frac{n}{2} \sqrt{{( {λ}_{c} {c}_{l} + {λ}_{s} {d}_{l} )}^{2} + {( {λ}_{c} {d}_{l} + {λ}_{s} {c}_{l} )}^{2}} \\ and tan φ = \frac{{λ}_{c} {d}_{l} - {λ}_{s} {c}_{l}}{{λ}_{c} {c}_{l} + {λ}_{s} {d}_{l}} . & \end{matrix}$$

The input pattern of (20a) is referred to as “phased sinusoidal inputs.”

Lemma I: The expression for the output force, (26), can be simplified further by recognizing:

if l is odd [symbol] dₗ=0

if l is even [symbol] cₗ=0 (27)

Proof: Omitted.

The output force can, therefore, be described as:

$$F = \{ \begin{matrix}π {c}_{l} ( {λ}_{c} cos l θ - {λ}_{x} sin l θ ) & if l is odd \\ π {d}_{l} ( {λ}_{x} cos l θ + {λ}_{c} sin l θ ) & if l is even\end{matrix} \qquad ( 28 )$$

Alternatively, in terms of the parameters in (20a) and (23):

$$\begin{matrix}C = \{ \begin{matrix}\frac{n}{2} {c}_{l} {U}_{l} & if l is odd \\ \frac{n}{2} {d}_{l} {U}_{l} & if l is even\end{matrix} & ( 29 a ) \\ ϕ = \{ \begin{matrix}- α & if l is odd \\ \frac{π}{2} - α & if l is even\end{matrix} & ( 29 b )\end{matrix}$$

### E. Input Signal Set That Produces Single Output

Provided that the l^{th} harmonic input (20a) induces only the l^{th} harmonic output force, the effect of the input harmonics outside 1≦l≦p+1 is examined. Interestingly, a bias term th as well as higher order harmonics greater than p+1 in the input do not affect the output force.

Proposition 3: If

$$R \leq ⌊ \frac{n}{2} ⌋$$

and the input signal is of the form:

$${u}_{i , R} ( {θ}_{i}^{0} ) = {\sum }_{r = p + 2}^{R} {U}_{r} cos ( r {θ}_{i}^{0} - {γ}_{r} ) \qquad ( 30 )$$

then the output is identically equal to 0 for all conditions:

$$\begin{matrix}{F}_{R} ( {u}_{i , R} ) = {\sum }_{q = 1}^{p + 1} {\sum }_{i = 1}^{n} [ \begin{matrix}( {c}_{q} cos q θ + {d}_{q} sin q θ ) cos q {θ}_{i}^{0} + \\ ( {d}_{q} cos q θ - {c}_{q} sin q θ ) sin q {θ}_{i}^{0}\end{matrix} ] {u}_{i , R} ( {θ}_{i}^{0} ) \\ = 0 , ∀ θ\end{matrix} \qquad ( 31 )$$

Proof: Consider the product between the q^{th} term in (31) and the r^{th} term involved in u_{i,R}(θᵢ⁰).

$${F}_{r , q} = {\sum }_{i = 1}^{n} [ ( {c}_{q} cos q θ + {d}_{q} sin q θ ) cos q {θ}_{i}^{0} + ( {d}_{q} cos q θ - {c}_{q} sin q θ ) sin q {θ}_{i}^{0} ] {U}_{r} cos ( r {θ}_{i}^{0} - {γ}_{r} ) \qquad ( 32 )$$

Converting the parameters c_{q} and d_{q} into amplitude A_{q}=√\sqrt{c_{q}²d_{q}²} and phase

$$tan {α}_{q} = \frac{{c}_{q}}{{d}_{q}} , tan {β}_{q} = \frac{{d}_{q}}{- {c}_{q}}$$

and further converting Uᵣ and γᵣ into ρ_{c,r} ρ_{s,r} where

$${U}_{r} = \sqrt{{ρ}_{o , r}^{2} + {ρ}_{x , f}^{2}} and tan {γ}_{r} = \frac{{ρ}_{s , j}}{{ρ}_{c , r}} , \qquad ( 32 )$$

can be rewritten as:

$${F}_{r , q} = {A}_{q} [ {ρ}_{c , r} sin ( q θ + {α}_{q} ) {\sum }_{i = 1}^{n} [ cos q {θ}_{i}^{0} cos r {θ}_{i}^{0} ] + {ρ}_{x , r} sin ( q θ + {α}_{q} ) {\sum }_{i = 1}^{n} [ cos q {θ}_{i}^{0} sin r {θ}_{i}^{0} ] + {ρ}_{c , r} sin ( q θ + {β}_{q} ) {\sum }_{i = 1}^{n} [ sin q {θ}_{i}^{0} cos r {θ}_{i}^{0} ] + {ρ}_{s , r} sin ( q θ + {β}_{q} ) {\sum }_{i = 1}^{n} [ sin q {θ}_{i}^{0} sin r {θ}_{i}^{0} ] ] \qquad ( 33 )$$

It is important to note several properties of q and r. First, q is always less than r due to the definition of the ranges of the summations: 1≦q≦p+1 and p+2≦r≦R≦└n/2┘. Second, the sum of q and r is always strictly less than n: q+r<2R≦n. Now, if the first summation in (33) is taken and a trigonometric identity is used, the following expression is obtained:

$${\sum }_{i = 1}^{n} cos q {θ}_{i}^{0} cos r {θ}_{i}^{0} = \frac{1}{2} [ {\sum }_{i = 1}^{n} [ cos ( ( r - q ) {θ}_{i}^{0} ) ] + {\sum }_{i = 1}^{n} [ cos ( ( r + q ) {θ}_{i}^{0} ) ] ] = 0 \qquad ( 34 )$$

where the same properties utilized in Proposition 1 are used, because r−q>0 and r+q<n. Similarly, the other summations in (33) vanish for all r and q. Therefore. F_{R} vanishes for all θ.

Remark 2: This property is a mathematical expression of the redundancy within the system. Given that there are a greater number of inputs than outputs, there should be a significant null space within the input space. Furthermore, exploiting this property, along with superposition i.e. the sum of two inputs yields the sum of their individual outputs, provides us with the freedom to select inputs that generate a specified output force, yet optimize other criteria.

### F. Product of Parameter Variation: Force Ripple

It was previously assumed that all the Units are identical and assembled perfectly, having no misalignment or offset. If this assumption is violated, all the features of poly-actuators exploiting the harmonic natures cannot be fully utilized. This section considers an effective method for characterizing the overall change in output force, i.e. the force ripple, for the purpose of compensating for it later. For simplicity, this analysis considers only variations in the nonlinear stiffness terms however, the same technique can be applied to other variations where the result is more complex. Consider a modification to (6b)′:

$${g}_{s}^{′} ( y ) = {\sum }_{k = 0}^{m} {h}_{k}^{′} {y}^{k} , {h}_{k}^{′} = {h}_{k} + {\tilde{h}}_{k} \qquad {( 31 )}^{′}$$

where \tilde{h}ₖ is an unknown error within the stiffness parameters that varies with each Unit. Separating the error terms \tilde{h}ₖ from the ideal terms hₖ, the deviation of the output force \tilde{F} caused by \tilde{h}ₖ can be written as:

$$\tilde{F} = {\sum }_{i = 1}^{n} {\sum }_{k = 0}^{m} {\tilde{h}}_{k , i} {y}_{i}^{k} \frac{d {y}_{i}}{d x} \qquad {( 32 )}^{′}$$

Substituting (6) into (32)′, the following expression is obtained:

$$\begin{matrix}\tilde{F} = {\sum }_{i = 1}^{n} {\sum }_{k = 0}^{m} {\tilde{h}}_{k , i} {A}^{k + 1} ω {sin}^{k} {θ}_{i} cos {θ}_{i} \\ = {\sum }_{i = 1}^{n} {\sum }_{k = 1}^{m + 1} {\tilde{a}}_{k , i} sin k {θ}_{i} + {\tilde{b}}_{k , i} cos k {θ}_{i} \\ = {\sum }_{k = 1}^{m + 1} [ {\tilde{A}}_{k} cos k θ + {\tilde{B}}_{k} sin k θ ]\end{matrix} \qquad {( 33 )}^{′}$$

where Ãₖ and \tilde{B}ₖ are constants given by:

$${\tilde{A}}_{k} = {\sum }_{i = 1}^{n} ( {\tilde{a}}_{k , i} cos k {θ}_{i}^{0} + {\tilde{b}}_{k , i} sin k {θ}_{i}^{0} ) \\ {\tilde{B}}_{k} = {\sum }_{i = 1}^{n} ( {\tilde{b}}_{k , i} cos k {θ}_{i}^{0} - {\tilde{a}}_{k , i} sin k {θ}_{i}^{0} ) \qquad {( 34 )}^{′}$$

Rearranging the terms Ãₖ and \tilde{B}ₖ, the total error force can be expressed as a single summation over k:

$$\tilde{F} = {\sum }_{k = 1}^{m + 1} {\tilde{C}}_{k} sin ( k θ + {ψ}_{k} ) \qquad {( 35 )}^{′}$$

where \tilde{C}ₖ=\sqrt{Ãₖ²+\tilde{B}ₖ²} and

$$tan {ψ}_{k} = \frac{{\tilde{B}}_{k}}{{\tilde{A}}_{k}} .$$

This shows that any variations within the nonlinear stiffness terms will cause a force ripple that varies with position and can be appropriately modeled as a finite order sum of sines function. A similar analysis can be shown for the variations to the input term gᵤ(y,u), alignment errors in vertical y and horizontal x positions, and dynamic parameters μ and β. The consequence is less severe for the input coupling term, however, because of the mode selection property described in Proposition 2, i.e. only an error that influences the same mode as the input will be present. Furthermore, given that the dynamic parameters are smaller than the output and typically have less relative variation than the stiffness, the ripple associated with them is small.

### III. Control Synthesis

The major benefit of the implementation of the proposed algorithm (20a), provided the necessary conditions are met, is it does not require feedback or compensation of the individual Units. Instead the global parameters can be measured and it provides the necessary input for the desired behavior.

### A. Passive Force and Stiffness Properties

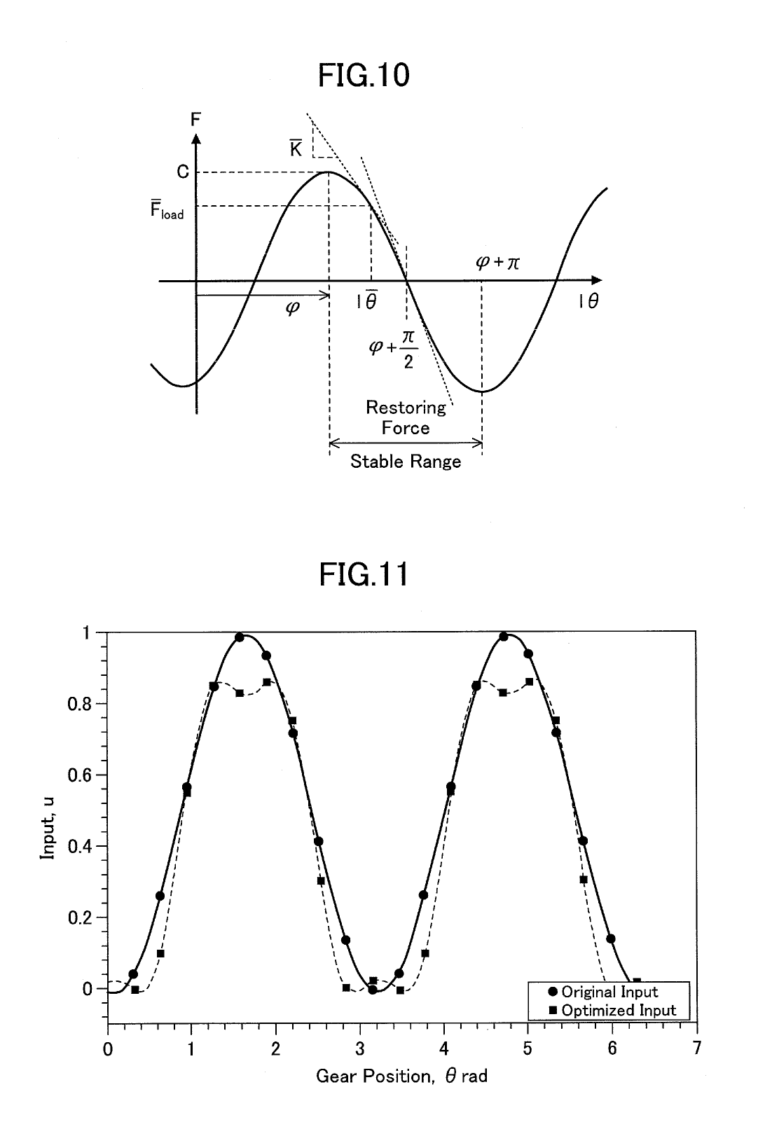

As discussed in Proposition 2, when constant inputs, defined by (20a), are applied to the n individual Units, the resultant force F is given by (23), which varies depending on the position θ, shown in FIG. 10.

If no external force acts on the output rod, the poly-actuator is in equilibrium at

$$l θ = ϕ \pm \frac{π}{2} ,$$

where the output force is zero. Note that the equilibrium at

$$l θ = ϕ + \frac{π}{2}$$

is a stable equilibrium, while the one at

$$l θ = ϕ - \frac{π}{2}$$

is unstable. A restoring force acts when the position deviates from the stable equilibrium, as long as the deviation is within the region of attraction: φ<lθ<φ+π. The poly-actuator is passively stable without feedback or any active controls within this region. Stiffness can be defined as the rate of change in the restoring force to the positional deviation.

$$K = - \frac{d F}{d x} = C ω l sin ( l θ - ϕ ) \qquad ( 35 )$$

See FIG. 10. Suppose that it is desired to make a specified position lθ̅ a stable equilibrium with a desired stiffness K̅. From (35):

$$\begin{matrix}ϕ = l \overline{θ} - \frac{π}{2} & ( 36 a ) \\ C = \frac{\overline{K}}{ω l} & ( 36 b )\end{matrix}$$

Substituting these into (29) yields the input magnitude U₁ and phase α that creates a stable equilibrium with stiffness K̅ at the position lθ̅.

In the case a constant load F̅_{load} must be borne at lθ̅:

F̅_{load}=Ccos(lθ̅−φ̅) (37)

with a desired stiffness K̅, the parameters C and φ can be found by solving (35) and (37).

$$\begin{matrix}ϕ = l \overline{θ} + {tan}^{- 1} ( \frac{\overline{K}}{{\overline{F}}_{load} ω l} ) & ( 38 a ) \\ C = \frac{{\overline{F}}_{load}}{cos ( l \overline{θ} - ϕ )} & ( 38 b )\end{matrix}$$

Note that, since the constant input function (20a) contains two parameters, U₁ and α, which determine C and φ, the poly-actuator can generate both desired force F̅_{load} and desired stiffness K̅ at a specified position lθ̅. Note, however, that the magnitude C is bounded C≦Cₘₐₓ, and therefore so are F̅_{load} and K̅.

### B. Input Shaping Exploiting the Null Space

The redundancy addressed in Proposition 3 can be exploited to generate a given output force while optimizing other criteria, such as the total electrical energy. Let

$$J = {\sum }_{i = 1}^{n} {u}_{i}^{2}$$

be a metric of the total electrical energy stored in the n Units. Higher order terms given by (30) can be superimposed together with a constant term to the input command (20a).

FIG. 11 illustrates how the redundancy can be exploited to find an optimal input that minimizes the electrical energy. Here a case where p<4,d₂≠0, and n=20 is considered. The solid curve indicates the inputs generated with one sinusoid of 1=2, i.e. the second harmonic. Superposing another spatial frequency component, e.g. the sixth harmonic, R=6, onto the second harmonic, a different input pattern that produces the same output force can be generated. The magnitude and phase of the sixth mode are free parameters that can be varied to minimize the electrical energy. The broken line in FIG. 11 is the optimal input curve that minimizes this electrical energy. Note that the peak value is significantly lowered. This configuration is able to reduce the stored electrical energy by 15%. In this way, harmonic inputs to a nonlinear reciprocating actuator such as the buckling PZT actuator can reduce an amplitude of an input to the nonlinear reciprocating actuator without any effect in an output of the poly-actuator.

### C. Force Control

Force control, in general, aims to generate a reference force regardless of the position and velocity of the system. Here, it is an object to synthesize a force control system to achieve this goal effectively by considering two issues. One is to generate the desired force F̅ efficiently. FIG. 10 indicates that the maximum amplitude of force for a given input is generated at lθ̅−φ=0,π or φ=lθ, lθ+π. At these points, the magnitude of the input command is:

$${U}_{l} = \{ \begin{matrix}\frac{2 \overline{F}}{{nc}_{l}} & if l is odd \\ \frac{2 \overline{F}}{{nd}_{l}} & if l is even\end{matrix} \qquad ( 39 )$$

The second point is that, since the output force in (23) varies depending on θ, the input command (20a) must be varied to compensate for the change. This requires a measurement of the current position \hat{θ}, which varies the input as:

$${u}_{i} ( {θ}_{l}^{0} , \hat{θ} ) = \{ \begin{matrix}\frac{2 \overline{F}}{{nc}_{l}} cos ( l ( {θ}_{i}^{0} + \hat{θ} ) ) & if l is odd \\ \frac{2 F}{{nd}_{l}} cos ( l ( {θ}_{i}^{0} + \hat{θ} ) - \frac{π}{2} ) & if l is even\end{matrix} \qquad ( 40 )$$

Substituting (40) into (23) yields the constant output force that was specified: F̅. An important feature of the above force control is that at the peak force position lθ*−φ=0,π, the stiffness is zero:

$${\frac{d F}{d θ} \vert}_{{θ}^{``}} = 0 ,$$

which implies that the sensitivity of the output force to positional deviation is minimized. In other words, although the measurement of \hat{θ} is inaccurate; or the compensation for the output force due to the positional change is not accurate, their effects upon the output force is small.

It should be noted that this control method does not close the loop around force. Instead, it is a feed-forward controller based on modeled or measured properties of the poly-actuator and a measurement of the position \hat{θ}. Trivially, the loop can be closed around position or force, given the necessary measurement and classic control techniques.

### D. Force Ripple Compensation

In the cases where the force ripple, \tilde{F}, can he expressed as a series of harmonic functions of a finite order: N, an initial calibration can be measured and a model of the ripple can be stored for online use. Therefore, combining all the force ripples caused by diverse sources of Unit variations, the total force ripple can be written as:

$${\hat{F}}_{ripple} ( θ ) = {\sum }_{κ = 1}^{N} {E}_{κ} sin ( κ θ + {φ}_{κ} ) \qquad {( 37 )}^{′}$$

The parameters E_{K} and φ_{K} may be determined through experiments. Spatial Fourier analysis of measured force ripple provides E_{K} and φ_{K}, K=1, . . . , N, that represent the aggregate effect of all the Unit variations.

Since the force ripple is a function of position alone, its effect can be compensated for by measuring the position of the poly-actuator, \hat{θ}.

$${\hat{F}}_{ripple} ( \hat{θ} ) = {\sum }_{κ = 1}^{N} {E}_{κ} sin ( κ \hat{θ} + {φ}_{κ} ) \qquad {( 38 )}^{′}$$

Subtracting \hat{F}ᵣᵢₚₚₗₑ from a nominal input command F̅ the ripple force is eliminated. This compensation is similar to the cogging torque compensation for a synchronous motor, but a) the ripple force model (37)′ contains at most 2N parameters regardless of the number of Units n or the stroke of the Transmission, and b) the compensation law (38)′ does not include Unit index, i, and thereby no individual Unit compensation is required, only the aggregate control.

### E. Input-Output Relation

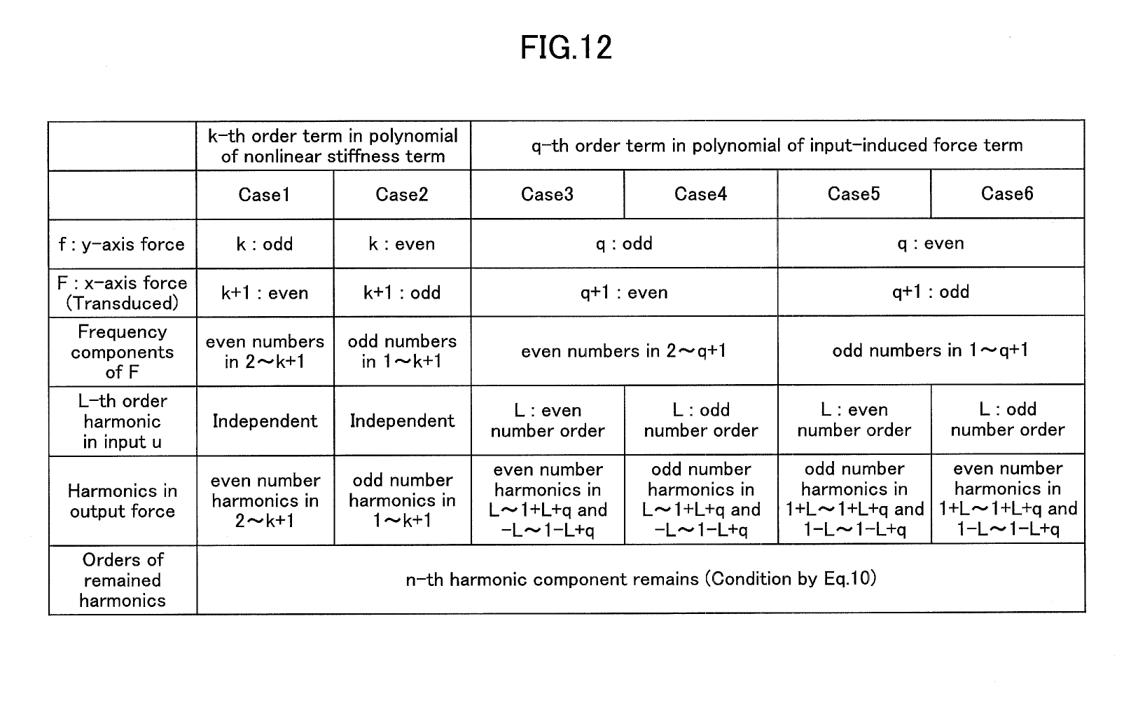

FIG. 12 shows a table representing a general relationship between a k-th order term in a polynomial of the nonlinear stiffness term, a q-th order term in a polynomial of the input-induced force term, an L-th order harmonic component in the input, harmonic components in the output force, and orders of remained harmonics in the output force.

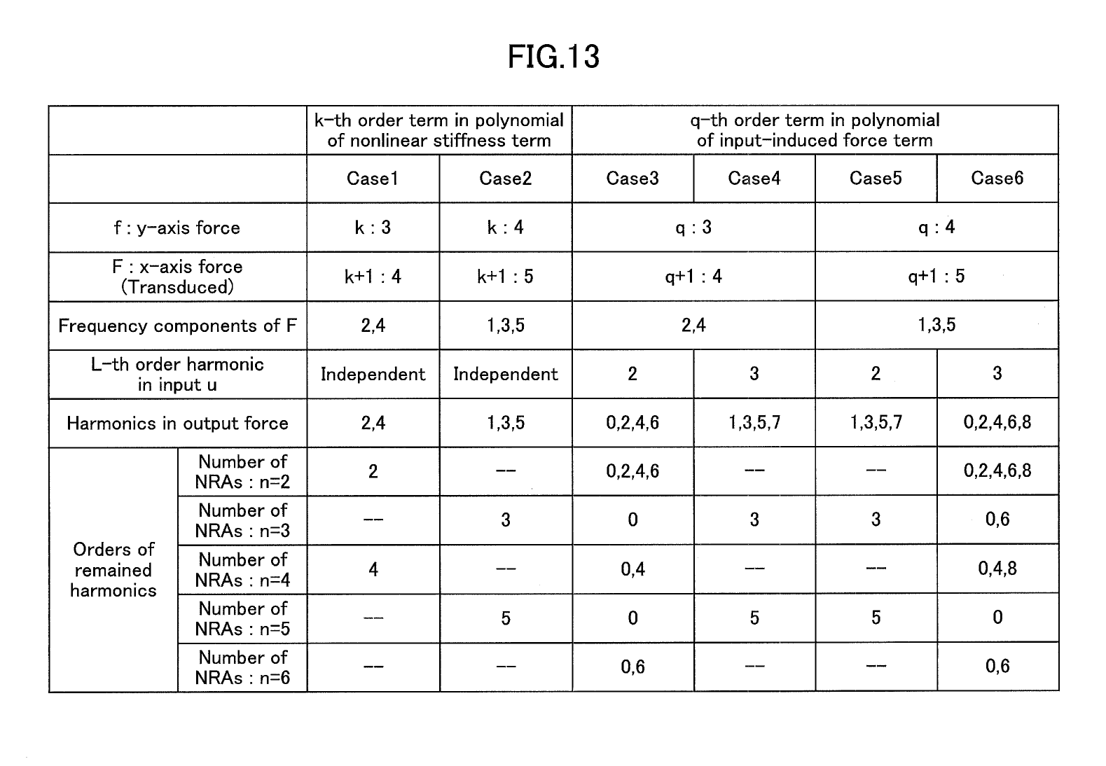

FIG. 13 shows a table representing a concrete relationship between a k-th order term in a polynomial of the nonlinear stiffness term, a q-th order term in a polynomial of the input-induced force term, an L-th order harmonic component in the input, harmonic components in the output force and orders of remained harmonics in the output force

In FIGS. 12 and 13, a first row (“f: y-axis force”) indicates an order of polynomial approximating a y-axis force f of an individual Unit. A second row (“F: x-axis force (Transduced)”) indicates an order of polynomial approximating an x-axis force transduced from the y-axis force. A third row (“Frequency components of F”) indicates orders of harmonic components in the x-axis force F. A fourth row (“L-th order harmonic in input u”) indicates orders of harmonic components in the input u. A fifth row (“Harmonics in output force”) indicates orders of harmonic components in the output force which is the sum of the x-axis forces. A sixth row (“Orders of remained harmonics”) indicates orders of explicit (non-cancelled) harmonic components in the output force. An NRA stands for a nonlinear reciprocating actuator such as the above buckling PZT actuator.

For example, a first column (“case 1”) in FIG. 12 indicates that, if an order of polynomial approximating the y-axis force f is an odd number k, an order of polynomial approximating the x-axis force becomes an even number k+1 and orders of harmonic components in the x-axis force F consist of even numbers in 2 to k+1 referring to the equation (11). The case 1 also indicates that the k-th order term in a polynomial of the nonlinear stiffness term is independent from the orders of harmonic components in the input u and that the orders of harmonic components in the output force consist of even numbers in 2 to k+1. On that basis, the case 1 indicates that the orders of explicit (non-cancelled) harmonic components are given by the equation (10).

Specifically, as in FIG. 13, the case 1 indicates that, if an order of polynomial approximating the y-axis force f is 3, an order of polynomial approximating the x-axis force becomes 4 and orders of harmonic components in the x-axis force F consist of 2 and 4. The case 1 also indicates that the 3rd order term in a polynomial of the nonlinear stiffness term is independent from the orders of harmonic components in the input u and that the orders of harmonic components in the output force consist of 2 and 4. On that basis, the case 1 indicates that the order of explicit (non-cancelled) harmonic component is 2 if the number of NRAs is 2, that the order of explicit (non-cancelled) harmonic component is 4 if the number of NRAs is 4, or that ail harmonic components are suppressed or cancelled if the number of NRAs is 3, 5, or 6. The same goes for the case 2.

A third column (“case 3”) in FIG. 12 indicates that, if an order of polynomial approximating the y-axis force f is an odd number q and if an order of a harmonic component in the input a is an even number L, the orders of harmonic components in the output force consist of even numbers in L to 1+L+q and −L to 1−L+q (see the equation (25)).

Specifically, as in FIG. 13, the case 3 indicates that, if an order of polynomial approximating the y-axis force f is 3 and if an order of a harmonic component in the input a is 2, the orders of harmonic components in the output force can consist of 0, 2, 4, and 6. On that basis, the case 3 indicates that the orders of explicit (non-cancelled) harmonic components can be 0, 2, 4, and 6 if the number of NRAs is 2, that the orders of explicit (non-cancelled) harmonic components can be 0 and 4 if the number of NRAs is 4, that the orders of explicit (non-cancelled) harmonic components can be 0 and 6 if the number of NRAs is 6, or that the order of explicit (non-cancelled) harmonic components can be 0 if the number of NRAs is 3 or 5.

The same goes for the case 4 to the case 6.

According to the above phase layout of the NRAs, ripples in the output force of the poly-actuator caused by the nonlinear stiffness term and/or the nonlinear input-induced force term can be suppressed or cancelled.

Also, according to the above harmonic inputs to the NRAs, ripples in the output force of the poly-actuator caused by both the nonlinear stiffness term and the nonlinear input-induced force term can be suppressed cancelled.

Also, according to the above phase layout of the NRAs, the output of the poly-actuator can be controlled by the single frequency sinusoidal input for the NRAs.

### IV. Implementation And Experiments

The above harmonic control methods have been implemented on a poly-actuator using PZT buckling Units. The force-displacement relationship of each Unit is given by the following non-linear function.

### A. Piezoelectric Buckling Mechanism as the Driving Unit

f=hᵢy+h₃y³+ηᵢyu+μÿ (39)′

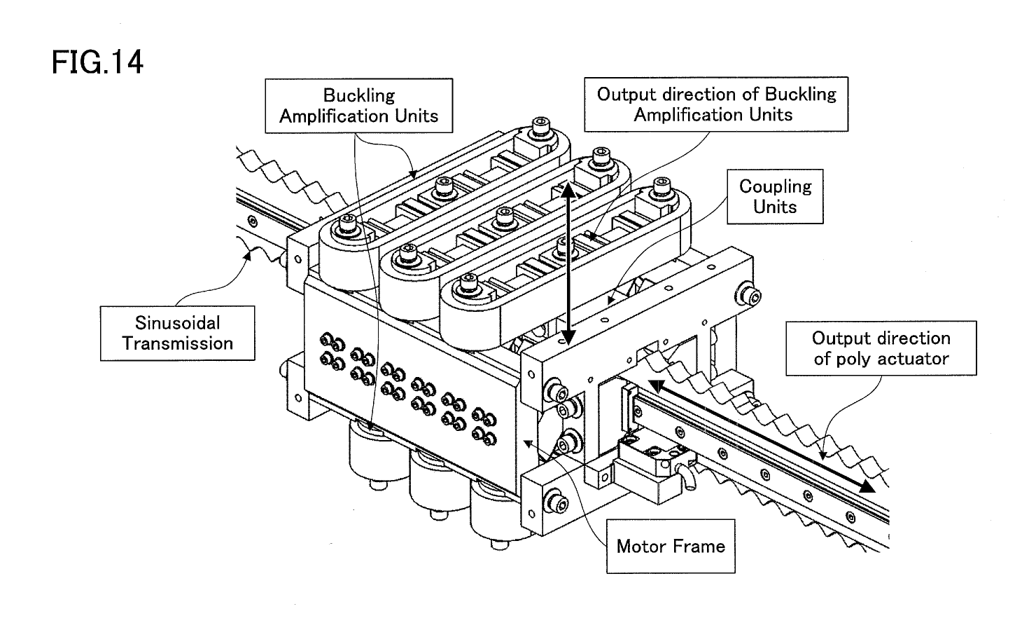

Six PZT buckling Units have been integrated into a harmonic poly-actuator: n=6. See FIG. 14. The number of actuators satisfies the requirement in (14b), n=6>m+1=4, so the poly-actuator output force, F, is independent of the nonlinear stiffness terms h₁ and h₃.

$$F = ( M + {M}_{eff} ) \hat{θ} + {\sum }_{i = 1}^{n} \frac{{η}_{1} {A}^{2} ω}{2} {u}_{i} sin 2 {θ}_{i} \qquad {( 40 )}^{′}$$

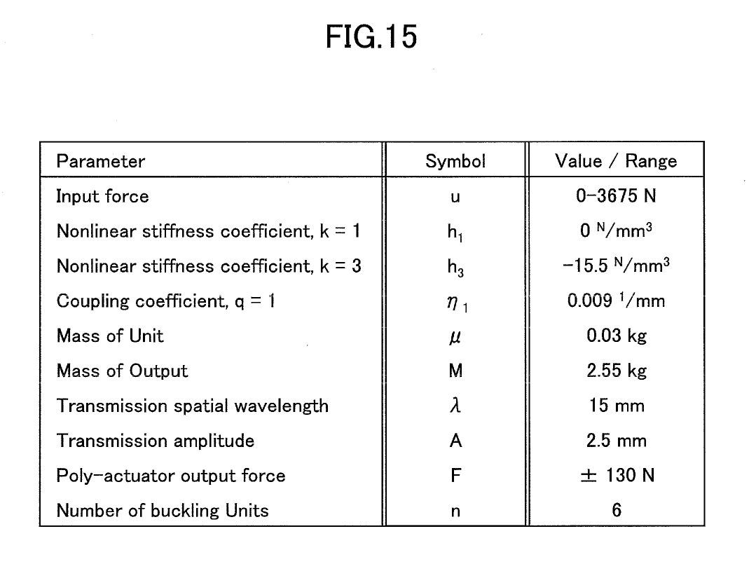

Note that c_{q}=0, ∀ q and d_{q}=0, ∀ q≠2, therefore there is only one choice for the input harmonic to produce a nonzero output force, that is 1=2. The necessary condition in (22) is also satisfied, n=6>l+p+1=4. The parameters in (39)′ and (40)′ for the prototype system are listed in FIG. 15.

### B. Force Control and Ripple Compensation Implementation

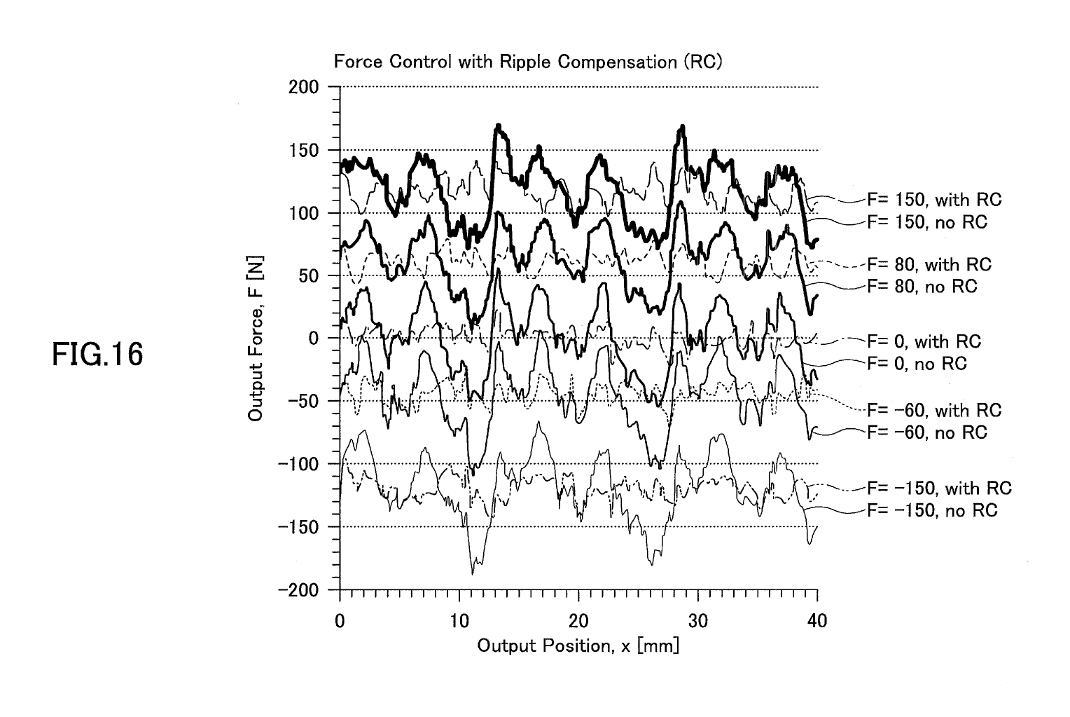

As analyzed previously, the output force becomes imbalanced when the Units are misaligned or have diverse force-displacement characteristics. FIG. 16 shows an experiment of the prototype poly-actuator commanded to produce several force ranging from −150 N to 150N with no compensation. On average, the output force is accurate, but due to the error, it fluctuates ±60 N peak-to-peak. The experiment was performed over the entire stroke of the Transmission, but a similar pattern of the output force fluctuation was observed in every 15 mm, which is the wavelength λ of the sinusoidal gear teeth.

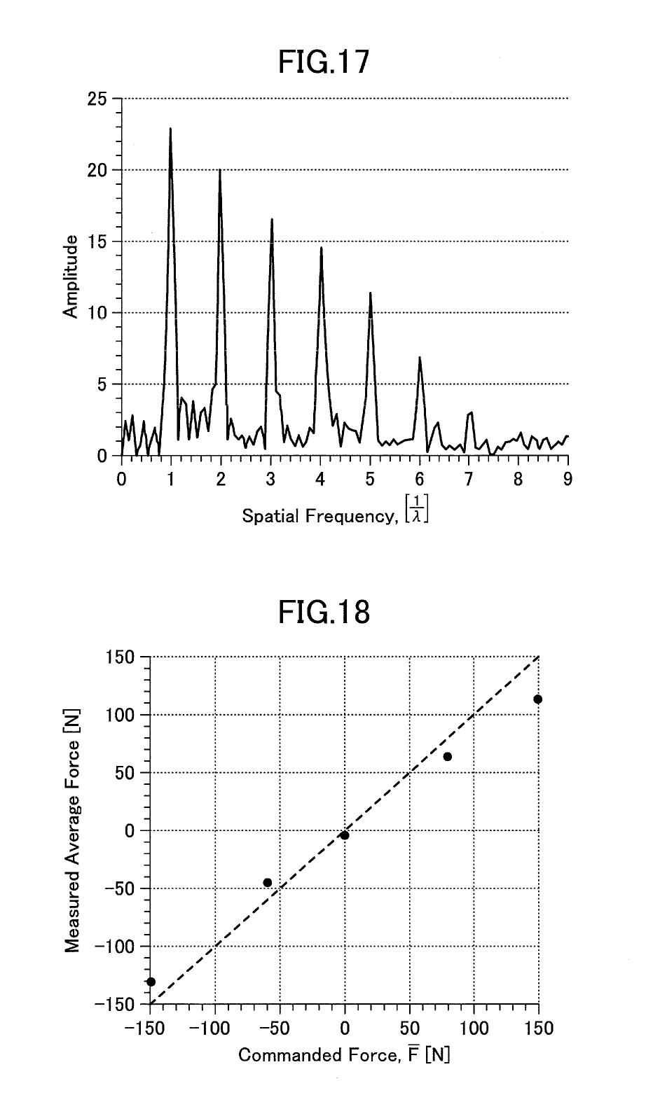

A spatial FFT of the output force, shown in FIG. 17, was used to confirm the claim in Section III-D that the force ripple is equal to a sum of sines with frequencies equal to that of the Transmission and a finite number of its harmonics. Note the first 6 harmonics have an amplitude significantly larger than the noise within the signal, while the higher order harmonics do not contribute.

Using the FFT and the measured data, a Fourier series based on the first 6 harmonics was fit to the data to create a model of the force ripple. This compensation method was tested using the model F̅_{f}.

The compensated force measurement is shown as the dashed lines in FIG. 16. The force ripple can be represented by the RMS value of the force over the wavelength of the Transmission. The Fourier model-based compensator reduced the RMS ripple by up to 290%. The ability to compensate the force ripple was limited at high commanded force due to saturation of the inputs uᵢ.

In addition, FIG. 18 shows the measured force of the compensated output averaged over one wavelength of the transmission compared to the commanded force F̅. Note that the actuator was not able to reach the expected peak forces due to losses including friction and the errors modeled within the force ripple.

These features were modeled using harmonic analysis including a nonlinear stiffness, linear dynamic parameters, and error within the Units. The analysis provided several insights and conditions that must be met including a minimum number of Units and the relative position of the Units along the Transmission, in order to take advantage of the harmonic features.

These results were applied to a harmonic poly-actuator comprised of six PZT Units. The feed-forward force control was tested and used in conjunction with force ripple compensation which reduced ripple by up to 290%.

### V. Conclusion

The harmonic poly-actuator has several inherent features due to the redundant inputs and sinusoidal Transmission. Provided several conditions are met including a minimum number of Units and the relative position of the Units along the Transmission, three critical features have been theoretically proven and experimentally tested in this embodiment.
Any term in the output force of the Unit that relies solely on the position of the Unit g(y) will have no effect on the output force of the poly-actuator.
Phased sinusoidal input functions given to the individual Units create an output force-displacement relationship with the same spatial frequency as the input functions, containing no other frequencies. Expressions relating the magnitude and phase of the input and output are provided.
It was shown that input functions based on the relative position with sufficiently high spatial frequencies have no effect on the output. Superposing the original input with the higher frequency produces the identical output but can foe optimized around additional input condition, e.g. stored electrical energy or peak input voltage.

These three properties were applied to harmonic poly-actuator comprised of six PZT buckling-amplified Units. The feed-forward force control was tested and used in conjunction with the necessary position measurement to produce a closed-loop position controller capable of positioning within 1 micrometer. Furthermore, an error analysis theoretically explained the observed force ripple phenomenon. Briefly, the discrepancies from Unit to Unit caused an imbalance from the ideal explained in Proposition 1. However, this force ripple can be sufficiently modeled as a sum of a finite number of sinusoids.

Further, the present invention is not limited to these embodiments, but various variations and modifications may be made without departing from the scope of the present invention.

What is claimed is:

1. A poly-actuator comprising:
an output unit having one or more cam portions; and
a plurality of nonlinear reciprocating actuators each of which has a follower mechanism connected to the one or more cam portions;
wherein the cam portions are formed by smooth periodically curved surfaces which guide rotational centers of the follower mechanisms along a sinusoidal trajectory with respect to a motion of the output unit,
each of the nonlinear reciprocating actuators has nonlinearity in output force-displacement characteristics,
the nonlinear reciprocating actuators are equally spaced in terms of a phase of the sinusoidal trajectory,
a total distance obtained by multiplication of the number of the nonlinear reciprocating actuators and an equal interval between the nonlinear reciprocating actuators is equal to a multiple of a wave length of the sinusoidal trajectory,
the equal interval is not equal to any multiple of the wave length,
the output force has a nonlinear stiffness term including a k-th order term,
if k is odd, orders of harmonic components of the sinusoidal trajectory in the output force consists of even numbers in 2 to k+1, and if k is even, orders of the harmonic components in the output force consists of odd numbers in 1 to k+1, and
multiples of the number of the nonlinear reciprocating actuators do not match the orders of the harmonic components in the output force.

2. The poly-actuator according to claim 1,
wherein, if the nonlinear stiffness term consists of a 3rd order term and if the number of the nonlinear reciprocating actuators is 2, 3, or 4, all of the harmonic components are suppressed.

3. The poly-actuator according to claim 1,
wherein the output force has a nonlinear input-induced force term including a q-th order term,
an input signal to each of the nonlinear reciprocating actuators includes at least an L-th order harmonic component of the sinusoidal trajectory,
the harmonic component in the input signal has a phase shift between the nonlinear reciprocating actuators,
the phase shift is equal to the equal interval between the nonlinear reciprocating actuators,
if q is odd and L is even, orders of the harmonic components in the output force consists of even numbers in absolute values of L to l+L+q and in −L to 1−L+q,
if q is odd and L is odd, orders of the harmonic components in the output force consists of odd numbers in absolute values of L to 1+L+q and in −L to 1−L+q,
if q is even and L is even, orders of the harmonic components in the output force consists of odd numbers in absolute values of 1+L to 1 + L+q and in 1−L to 1−L+q,
if q is even and L is odd, orders of the harmonic components in the output force consists of odd numbers in absolute values of 1+L to 1+L+q and in 1−L to 1−L+q, and
multiples of the number of the nonlinear reciprocating actuators do not match the orders of harmonic components in the output force.

4. The poly-actuator according to claim 3,
in a case where the input-induced force term consists of a 3rd order term, the input signal consists of a 2nd order harmonic component, and the number of the nonlinear reciprocating actuators is 3 or 5, or
in a case where the input-induced force term consists of a 4th order term, the input signal consists of a 3rd order harmonic component, and the number of the nonlinear reciprocating actuators is 5,
all of the harmonic components other than 0th order harmonic component in the output force are suppressed.

5. The poly-actuator according to claim 3,
in a case where the input-induced force term consists of a 3rd order term, the input signal consists of a 3rd order harmonic component, and the number of the nonlinear reciprocating actuators is 2, 4, or 6, or
in a case where the input-induced force term, consists of a 4th order term, the input signal consists of a 2nd order harmonic component, and the number of the nonlinear reciprocating actuators is 2, 4, or 6,
all of the harmonic components in the output force are suppressed.

6. The poly-actuator according to claim 3,
wherein at least one of higher order harmonic components is superposed with respect to the L-th order harmonic component in the input signal,
an amplitude and/or a phase shift of the at least one of higher order harmonic components is controlled, and
a frequency of the superposed harmonic component is equal to a frequency to be suppressed.

7. The poly-actuator according to claim 3,
wherein at least one of higher order harmonic components is superposed with respect to the L-th order harmonic component in the input signal, and
an order of the at least one of higher order harmonic components is an odd number multiple of L.
